(19) United States
(12) Patent Application Publication
(10) Pub. No.: US 2026/0190771 A1
(43) Pub. Date: Jul. 2, 2026

(54) DISPLAY PANEL AND MANUFACTURING METHOD THEREFOR, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Tinghua SHANG, Beijing (CN); Yi ZHANG, Beijing (CN); Yang ZHOU, Beijing (CN); Zhen LIU, Beijing (CN); Ying LIU, Beijing (CN); Xiaoliang GUO, Beijing (CN); Xueguang HAO, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/857,826

(22) PCT Filed: Sep. 12, 2023
(86) PCT No.: PCT/CN2023/118382

§ 371 Date: Oct. 18, 2024

(51) Int. Cl. H10K 59/80; H10K 59/12

(52) U.S. Cl. CPC H10K 59/8723; H10K 59/1201; H10K 59/873

(57) ABSTRACT

Embodiments of the present disclosure provide a display panel. The display panel includes a base substrate, wherein the base substrate includes an opening region and a display region, the display region surrounding the opening region. The plurality of isolation pillars are disposed on a first surface of the base substrate, and the plurality of isolation pillars are circular and surround the opening region. The isolation pillars include a first pillar made of an insulating material, and an isolation groove surrounding the opening region is disposed at both sides of the first pillar.

### CROSS-REFERENCE TO RELATED APPLICATION

The present disclosure is a U.S. national phase application based on PCT/CN2023/118382, filed on Sep. 12, 2023, the content of which is herein incorporated by reference in its entirety.

### TECHNICAL FIELD

The present disclosure relates to the field of display technologies, and in particular, relates to a display panel, a manufacturing method therefor, and a display device.

### BACKGROUND

Display devices have a wide range of application scenarios in life, such as cell phones, tablets, and other electronic devices. The display panel is an important component of the display device.

### SUMMARY

Embodiments of the present disclosure provide a display panel, a manufacturing method therefor, and a display device. The technical solutions are described as follows.

In a first aspect, a display panel is provided. The display panel includes a base substrate and a plurality of isolation pillars. The base substrate includes an opening region and a display region, wherein the display region surrounds the opening region; the plurality of isolation pillars are disposed on a first surface of the base substrate, and the plurality of isolation pillars are circular and surround the opening region; wherein each of the plurality of isolation pillars includes a first pillar made of an insulating material, wherein an isolation groove surrounding the opening region is disposed at both sides of the first pillar, the first pillar has a first top surface away from the first surface, a first bottom surface close to the first surface, and a first sidewall and a second sidewall between the first top surface and the first bottom surface.

Optionally, the first sidewall is close to the opening region and is recessed in a direction away from the opening region; and/or the second sidewall is away from the opening region and is recessed in a direction close to the opening region.

Optionally, each of the plurality of isolation pillars further includes a first isolation ring, wherein the first isolation ring is disposed on a side, close to the first surface, of the first pillar, and the first isolation ring is made of a non-insulating material.

Optionally, the first isolation ring covers a bottom of the isolation groove; or the first isolation ring includes a first subring and a second subring which are sequentially disposed in a radially outward direction centered on a center of the opening region, wherein the first subring is disposed at an edge, close to the first sidewall, of the first bottom surface, and the second subring is disposed at an edge, close to the second sidewall, of the first bottom surface.

Optionally, each of the plurality of isolation pillars further includes a second isolation ring, wherein the second isolation ring is disposed on a side, away from the first surface, of the first pillar, and the second isolation ring is made of a non-insulating material.

Optionally, the second isolation ring covers the first top surface; or the second isolation ring includes a third subring and a fourth subring which are sequentially disposed in a radially outward direction centered on a center of the opening region, wherein the third subring is disposed at an edge, close to the first sidewall, of the first top surface, and the fourth subring is disposed at an edge, close to the second sidewall, of the first top surface.

Optionally, each of the plurality of isolation pillars further includes a second pillar, wherein the second pillar is disposed on a side, away from the first surface, of the first pillar and is made of an insulating material.

Optionally, each of the plurality of isolation pillars further includes a third isolation ring, wherein the third isolation ring is disposed on a side, away from the first surface, of the second pillar and is made of a non-insulating material.

Optionally, the display panel further includes at least one block wall, wherein the at least one block wall is disposed in a layer in which the second pillar is disposed, and is connected to a layer in which the second isolation ring is disposed and a layer in which the third isolation ring is disposed.

Optionally, the at least one block wall includes one first block wall, disposed on a side, close to the opening region, of a first isolation groove, wherein the first isolation groove is an isolation groove closest to the opening region of a plurality of isolation grooves; and/or at least one second block wall, wherein each second block wall is disposed in one second pillar, and the second block wall is connected to the second isolation ring and the third isolation ring.

Optionally, each of the plurality of isolation pillars further includes a second pillar, wherein the second pillar is disposed on a side, away from the first surface, of the first pillar and is made of an insulating material.

Optionally, in a radial direction of the opening region, a distance between an edge, close to the opening region, of an orthographic projection of the first top surface on the first surface and a contour line, away from the opening region, of an orthographic projection of the first sidewall on the first surface ranges from 0.1 to 2.0 μm; and/or in the radial direction of the opening region, a distance between an edge, away from the opening region, of the orthographic projection of the first top surface on the first surface and a contour line, close to the opening region, of an orthographic projection of the first sidewall on the first surface ranges from 0.1 to 2.0 μm.

Optionally, a dimension of the first top surface in a radial direction of the opening region ranges from 3 to 10 μm, and/or a distance between the first top surfaces of the first pillars of two adjacent isolation pillars ranges from 5 to 20 μm.

Optionally, the second pillar has a second bottom surface close to the first surface, a second top surface away from the first surface, and a third sidewall and a fourth sidewall between the second top surface and the second bottom surface; wherein the third sidewall is close to the opening region and recessed in a direction away from the opening region, and/or, the fourth sidewall is away from the opening region and recessed in a direction close to the opening region.

Optionally, in a radial direction of the opening region, a distance between an edge, close to the opening region, of an orthographic projection of the second top surface on the first surface and a contour line, away from the opening region, of an orthographic projection of the third sidewall on the first surface ranges from 0.1 to 2.0 μm; and/or in the radial direction of the opening region, a distance between an edge, away from the opening region, of an orthographic projection of the second top surface on the first surface and a contour line, close to the opening region, of an orthographic projection of the third sidewall on the first surface ranges from 0.1 to 2.0 μm.

Optionally, a radial width of the second top surface is equal to a radial width of the first top surface, or the radial width of the second top surface is less than the radial width of the first top surface.

Optionally, the first pillar is made of an inorganic insulating material, and the second pillar is made of an inorganic insulating material or an organic insulating material.

Optionally, the display panel further includes a driving circuit layer and an anode layer which are sequentially stacked on the first surface, wherein the plurality of isolation pillars are disposed in the same layer as one or more layers in the driving circuit layer.

Optionally, the display panel further includes a dam structure, wherein the dam structure (15) is disposed on a surface, away from the first surface, of one of the plurality of isolation pillars (12), and the dam structure surrounds the opening region.

Optionally, the display panel further includes a block ring, wherein the block ring is disposed on a surface, away from the first surface, of one of the plurality of the isolation pillars, and the block ring surrounds the dam structure; and in a direction perpendicular to the first surface, a dimension of the block ring is less than a dimension of the dam structure.

Optionally, the plurality of isolation pillars includes a plurality of outer isolation pillars and a plurality of inner isolation pillars, wherein the plurality of outer isolation pillars are disposed on a side, close to the opening region, of the dam structure, and the plurality of inner isolation pillars are disposed on a side, away from the opening region, of the dam structure; and a groove is disposed on a surface, away from the first surface, of at least one outer isolation pillar of the plurality of outer isolation pillars, and the display panel further includes a filling structure disposed in the groove.

Optionally, at least a portion of the isolation pillar is made of an inorganic insulating material, at least a portion of the groove is disposed in the portion of the isolation pillar made of the inorganic insulating material, and the filling structure is made of an organic insulating material.

In another aspect, a method for manufacturing a display panel is provided. The method includes: providing a base substrate, wherein the base substrate includes an opening region and a display region, the display region surrounding the opening region; and processing a plurality of isolation pillars on a first surface of the base substrate; wherein the plurality of isolation pillars are circular and surround the opening region, each of the plurality of isolation pillars includes a first pillar made of an insulating material, wherein an isolation groove surrounding the opening region is disposed at both sides of the first pillar, the first pillar has a first top surface away from the first surface, a first bottom surface close to the first surface, and a first sidewall and a second sidewall between the first top surface and the first bottom surface.

In still another aspect, a display device is provided. The display device includes a power supply circuit and the above display panel, wherein the power supply circuit supplies power to the display panel.

### BRIEF DESCRIPTION OF DRAWINGS

To describe the technical solutions in the embodiments of the present disclosure more clearly, the following briefly introduces the accompanying drawings required for describing the embodiments. It is obvious that the accompanying drawings in the following description show merely some embodiments of the present disclosure, and a person of ordinary skill in the art may still derive other drawings from these accompanying drawings without creative efforts.

FIG. 1 is a schematic diagram of a planar structure of a display panel according to some embodiments of the present disclosure;

FIG. 2 is a schematic diagram of a cross-sectional structure of a display panel according to some embodiments of the present disclosure;

FIG. 3 is a schematic diagram of an enlarged structure of the isolation pillar in FIG. 2;

FIG. 4 is a schematic diagram of a planar structure of an isolation pillar according to some embodiments of the present disclosure;

FIG. 5 is a schematic diagram of a cross-sectional structure of another isolation pillar according to some embodiments of the present disclosure;

FIGS. 6 to 17 are schematic diagrams of a cross-sectional structure close to an opening region of another display panel according to some embodiments of the present disclosure;

FIG. 18 is a schematic diagram of a cross-sectional structure of another display panel according to some embodiments of the present disclosure;

FIG. 19 is a schematic flow diagram of a method for manufacturing a display panel according to some embodiments of the present disclosure;

FIG. 20 is a schematic diagram of a flow of processing an isolation pillar according to some embodiments of the present disclosure; and

FIGS. 21 to 32 are schematic diagrams of a flow of processing another isolation pillar according to some embodiments of the present disclosure.

### REFERENCE SIGNS

11—base substrate;
A—display region; B—opening region; C—first surface
12—isolation pillar;
121—first pillar;
121a—first top surface; 121b—first sidewall;
121c—second sidewall; 121d—first bottom surface;
122—first isolation ring;
1221—first subring;
1222—second subring;
123—second isolation ring;
1231—third subring;
1232—fourth subring;
124—second pillar;
124a—second top surface; 124b—third sidewall;
124c—fourth sidewall; 124d—second bottom surface;
125—third isolation ring;
125a—first block wall;
13—driving circuit layer;
1301—light-shielding layer;
1302—first gate layer;
1303—second gate layer;
1304—third gate layer;
1305—first source-drain layer;
1306—second source-drain layer;
1307—first semiconductor layer;
1308—second semiconductor layer;
1309—buffer layer;
1310—first gate insulating layer;
1311—first insulating layer;
1312—second gate insulating layer;
1313—third gate insulating layer;
1314—interlayer dielectric layer;
1315—passivation layer;
1316—first planarization layer;
1317—second planarization layer;
14—light-emitting function layer;
141—anode layer;
142—pixel definition layer;
143—light-emitting layer;
144—cathode layer;
15—dam structure;
16—block ring; and
17—filling structure.

### DETAILED DESCRIPTION

For clearer descriptions of the objectives, technical solutions, and advantages of the present disclosure, embodiments of the present disclosure are described in further detail hereinafter with reference to the accompanying drawings.

The terms in the embodiments portion of the present disclosure are used only for the purpose of explaining the embodiments of the present disclosure and are not intended to limit the present disclosure. Unless otherwise defined, technical terms or scientific terms in the embodiments of the present disclosure shall have the ordinary meaning understood by a person of ordinary skill in the art to which the present disclosure belongs. The terms “first,” “second,” “third,” and the like used in the description of the patent application and the claims of the present disclosure do not indicate any order, number, or importance, but are merely used to distinguish different components. Similarly, the words “a” or “one” and similar terms do not indicate a limitation of quantity, but rather the existence of at least one. Similar terms such as “includes” or “contains” mean that the components or objects appearing prior to “includes” or “contains” encompasses the components or objects that appearing upon “includes” or “contains”, and do not exclude other components or objects. Orientation terms mentioned in the present disclosure, such as “top”, “bottom”, “up”, “down”, “left”, “right”, or the like, are only references to the orientation of the accompanying drawings. Therefore, the orientation terms used are intended to better and more clearly illustrate and understand the present disclosure embodiments, and do not indicate or imply that the device or component referred to must have a particular orientation, or be constructed and operated in a particular orientation, which are not to be construed as a limitation of the embodiments of the present disclosure.

In the related art, the display panel includes a base substrate and a plurality of isolation pillars. The substrate includes an opening region and a display region, and the display region surrounds the opening region. The plurality of isolation pillars are disposed on the first surface of the base substrate, and the plurality of isolation pillars are circular and surround the opening region. The isolation pillars are configured to divide a film layer (e.g., a light-emitting layer) disposed on a side, away from the first surface, of the isolation pillars, which blocks external water and oxygen from extending from the edge of the opening region along the light-emitting material to the display region and causing poor display effect. Most of the isolation pillars are I-shaped structures including a plurality of metal layers.

However, electrical signals in the display region are transmitted to the vicinity of the opening region through the metal layers in the isolation pillar, resulting in electrochemical corrosion in the vicinity of the opening region and encapsulation failure.

FIG. 1 is a schematic diagram of a planar structure of a display panel according to some embodiments of the present disclosure. As shown in FIG. 1, the display panel includes a base substrate 11 and a plurality of isolation pillars 12. The base substrate 11 includes an opening region B and a display region A, and the display region A surrounds the opening region B. The plurality of isolation pillars are circular and surround the opening region B.

It should be noted that the substrate 11 illustrated in FIG. 1 is an example that the substrate 11 includes one opening region B. In other embodiments, the number of opening regions B is more than one.

In the embodiments of the present disclosure, the opening region B is configured to accommodate an electronic device. The electronic device may be a camera module, a fingerprint module, or other modules that need to receive external light.

The base substrate 11 further includes a peripheral region (not shown) that surrounds the display region A. The display region A includes a plurality of pixels arranged in an array. The peripheral region is configured to be arranged with peripheral traces and the like, so as to control the pixels to emit light and control the display region A to display an image.

Exemplarily, the display panel is an organic light-emitting diode (OLED) display panel, a quantum dot light-emitting diode (QLED) display panel, or the like, which is not limited in the embodiments of the present disclosure.

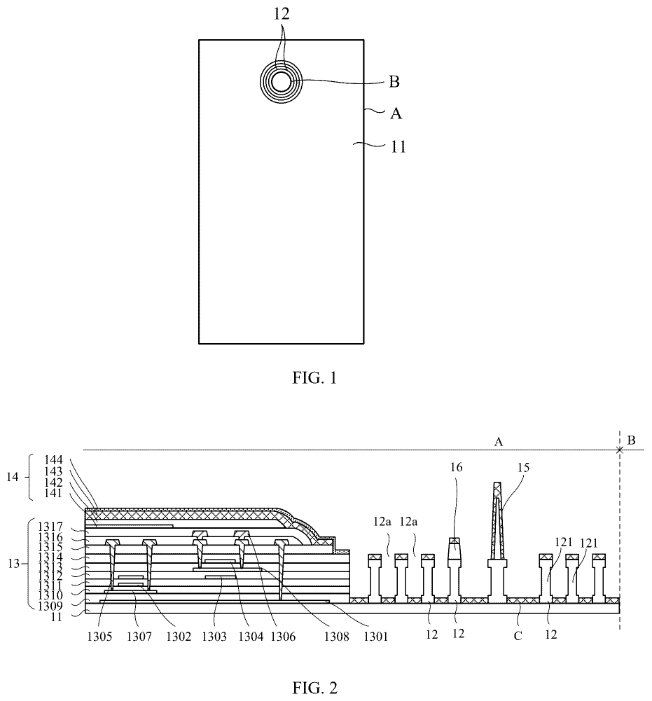

FIG. 2 is a schematic diagram of a cross-sectional structure of a display panel according to some embodiments of the present disclosure. As shown in FIG. 2, the plurality of isolation pillars 12 are disposed on a first surface C of the base substrate. Each of the plurality of isolation pillars 12 includes a first pillar 121 made of an insulating material. Isolation grooves 12a surrounding the opening region B are disposed on both sides of the first pillar 121. Herein, the both sides of the first pillar 121 refer to a side close to the opening region B and a side far away from the opening region B.

As the first pillar in the embodiments of the present disclosure is made of the insulating material, the first pillar can block the electrical signals (e.g., VSS signals) from being transmitted from the display region to the vicinity of the opening region, such that the undesirable encapsulation failure caused by the electrochemical corrosion in the vicinity of the opening region due to energization is avoided. Typically, an isolation pillar is configured to isolate the film layers, such as the light-emitting layer and the cathode layer, disposed on the isolation pillar. In the case that the cathode layer is isolated, the cathode layer on both sides of the first pillar 121 is insulated, such that VSS signals can be avoided from being transmitted from the display region to the vicinity of the opening region.

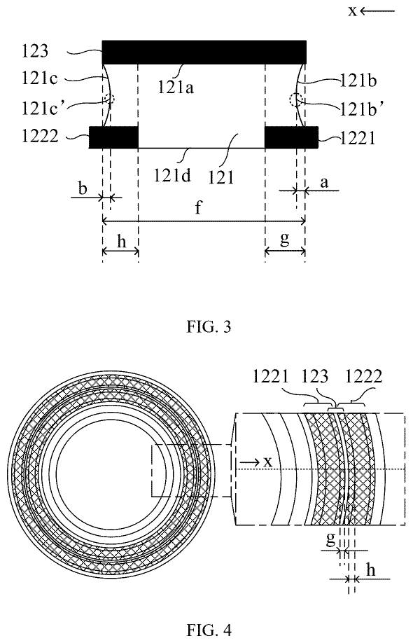

FIG. 3 is a schematic diagram of an enlarged structure of the isolation pillar in FIG. 2. As shown in FIGS. 2 and 3, the isolation pillar 12 includes a first pillar 121, the first pillar 121 has a first top surface 121a away from the first surface C, a first bottom surface 121d close to the first surface C, and a first sidewall 121b and a second sidewall 121c between the first top surface 121a and the first bottom surface 121d. The first sidewall 121b is close to the opening region B and is recessed in a direction away from the opening region B. The second sidewall 121c is away from the opening region B and is recessed in a direction close to the opening region B. In this way, an I-shaped structure can be formed, which is conducive to naturally isolating the film layer on the isolation pillar 12 and simplifying the manufacturing process of the display panel.

Exemplarily, the first sidewall 121b and the second sidewall 121c are both arc-shaped recessed. The present disclosure embodiments do not limit the shape of the recess, as long as the recess can isolate the film layer on the isolation pillar 12.

Optionally, in the radial direction x of the opening region B, the distance between the edge, close to the opening region B, of the orthographic projection of the first top surface 121a on the first surface C and the contour line, away from the opening region B, of the orthographic projection of the first sidewall 121b on the first surface C ranges from 0.1 μm to 2.0 μm. That is, the first recessed line ring 121b′ that is farthest away from the opening region B is disposed on the first sidewall 121b. The distance a between the projection of the first recessed line ring 121b′ on the first surface C and the edge, close to the opening region B, of the orthographic projection of the first top surface 121a on the first surface C ranges from 0.1 μm to 2.0 μm. The recess having the range of dimension enables the I-shaped structure to have a better isolation effect. The larger dimension of the recess affects the support ability of the first pillar 121, and a smaller dimension of the recess causes the I-shape less obvious and affects the isolation effect.

Optionally, in the radial direction x of the opening region B, the distance between the edge, away from the opening region B, of the orthographic projection of the first top surface 121a on the first surface C and the contour line, close to the opening region B, of the orthographic projection of the second sidewall 121c on the first surface C ranges from 0.1 μm to 2.0 μm. That is, the second recessed line ring 121c′ that is closest to the opening region B is disposed on the second sidewall 121c. The distance b between the projection of the second recessed line ring 121c′ on the first surface C and the edge, away from the opening region B, of the orthographic projection of the first top surface 121a on the first surface C ranges from 0.1 μm to 2.0 μm. The recess having the range of dimension enables the I-shaped structure to have a better isolation effect. The larger dimension of the recess affects the support ability of the first pillar 121, and a smaller dimension of the recess causes the I-shape less obvious and affects the isolation effect.

It should be noted that in the example shown in FIG. 3, both the first sidewall 121b and the second sidewall 121c are provided with recesses. In other embodiments, only the first sidewall 121b or only the second sidewall 121c is provided with a recess. This unilaterally recess structure is also capable of isolating the film layer on the isolation pillar 12.

Optionally, in the radial direction x of the opening region B, the dimension f the first top surface 121 ranges from 3 μm to 10 μm.

Optionally, in the radial direction x of the opening region B, the distance between the first top surfaces 121a of two adjacent first pillars 121 ranges from 5 μm to 20 μm.

In the case that the isolation pillar 12 includes the first pillar 121, the radial dimension of the first top surface 121a represents the size of the isolation pillar 12. The distance in the radial direction of the two adjacent first top surfaces 121a represents the distance between the two adjacent isolation pillars 12, and the isolation pillar 12 having this dimension is not too narrow for poor support, nor too wide for unfavorable narrow bezel design.

Optionally, as shown in FIG. 3, the isolation pillar 12 further includes a first isolation ring 122. The first isolation ring 122 is disposed on the side, close to the first surface C, of the first pillar 121 and covers the bottom of the isolation groove 12a. The first isolation ring 122 is made of a non-insulating material. In this way, the first isolation ring 122 is able to act as an etching block layer during the formation of the first pillar 121 to avoid adverse effects on the structure underneath the first isolation ring 122.

Exemplarily, as shown in FIG. 3, the first isolation ring 122 includes a first subring 1221 and a second subring 1222 which are sequentially disposed in a radially outward direction centered on the center of the opening region B. The first subring 1221 is disposed at an edge, close to the first sidewall 121b, of the first bottom surface 121d, and the second subring 1222 is disposed at an edge, close to the second sidewall 121c, of the first bottom surface 121d. The internally disconnected first isolation ring facilitates blocking electrical signals from passing through the isolation pillar.

Optionally, the isolation pillar 12 further includes a second isolation ring 123, and the second isolation ring 123 is disposed on a side, away from the first surface C, of the first pillar 121 and is made of a non-insulating material. Exemplarily, the second isolation ring 123 covers the first top surface 121a.

In the embodiments of the present disclosure, a contour line of an orthographic projection of the first pillar 121 on the first surface C is within an orthographic projection of the first isolation ring 122 on the first surface C. The contour line of an orthographic projection of the first pillar 121 on the first surface C is within an orthographic projection of the second isolation ring 123 on the first surface C. That is, the first isolation ring 122 is connected to at least an edge of the bottom of the first pillar 12, and the second isolation ring 123 is connected to at least an edge of the bottom of the second pillar 124. This arrangement facilitates the formation of the first pillar 121 having an I-shaped structure during a process such as etching.

“Bottom” herein refers to a side, close to the first surface C, of the structure, and “top” refers to a side, away from the first surface C, of the structure.

FIG. 4 is a schematic diagram of a planar structure of an isolation pillar according to some embodiments of the present disclosure. In conjunction with FIGS. 3 and 4, the radial dimension g of the overlapping region of the first subring 1221 with the second isolation ring 123 ranges from 3 μm to 10 μm, and the radial dimension h of the overlapping region of the second subring 1222 with the second isolation ring 123 range from 3 μm to 10 μm. Optionally, g ranges from 6 μm to 10 μm, and h ranges from 6 μm to 10 μm.

Referring again to FIG. 2, the display panel further includes a driving circuit layer 13 and a light-emitting layer 14 which are sequentially stacked on the first surface C. The light-emitting layer 14 includes an anode layer 141. The driving circuit layer 13 and the base substrate 11 are referred to as a driving backplane. Optionally, the driving circuit layer 13 includes a plurality of metal layers, one or more semiconductor layers, and a plurality of insulating layers disposed between the plurality of metal layers and the semiconductor layers.

Exemplarily, as shown in FIGS. 2 and 3, the driving backplane is low-temperature polycrystalline oxide (LTPO). The plurality of metal layers include a light-shielding layer 1301, a first gate layer 1302, a second gate layer 1303, a third gate layer 1304, a first source-drain layer 1305, and a second source-drain layer 1306 which are sequentially stacked on the first surface C. The driving circuit layer 13 includes a plurality of semiconductor layers, the plurality of semiconductor layers includes a first semiconductor layer 1307 and a second semiconductor layer 1308, the first semiconductor layer 1307 is disposed between the light-shielding layer 1301 and the first gate layer 1302, and the second semiconductor layer 1308 is disposed between the second gate layer 1303 and the third gate layer 1304.

Exemplarily, in the embodiments shown in FIG. 2, the plurality of insulating layers includes a buffer layer 1309, a first gate insulating layer 1310, a first insulating layer 1311, a second gate insulating layer 1312, a third gate insulating layer 1313, an interlayer dielectric layer 1314, a passivation layer 1315, a first planarization layer 1316, and a second planarization layer 1317. The light-shielding layer 1301, the buffer layer 1309, the first semiconductor layer 1307, the first gate insulating layer 1310, the first gate layer 1302, the first insulating layer 1311, the second gate layer 1303, the second gate insulating layer 1312, the second semiconductor layer 1308, the third gate insulating layer 1313, the third gate layer 1304, the interlayer dielectric layer 1314, the passivation layer 1315, the first source-drain layer 1305, the first planarization layer 1316, the second source-drain layer 1306, and the second planarization layer 1317 are sequentially stacked on the first surface C.

In the embodiments of the present disclosure, the isolation pillar 12 is disposed in the same layer as one or more of the driving circuit layers 13. Co-layer manufacturing simplifies the manufacturing process of the display panel.

The layer structures of the isolation pillar 12 are flexibly selected based on the requirements, such as the height of the isolation pillar 12, to be co-layered with which film layer of the driving backplane.

Optionally, the first pillar 121 is disposed in the same layer as at least one inorganic insulating layer of the plurality of insulating layers, such as with one or more of the buffer layer 1309, the first gate insulating layer 1310, the first insulating layer 1311, the second gate insulating layer 1312, the third gate insulating layer 1313, the interlayer dielectric layer 1314, and the passivation layer 1315. That is, the first pillar 121 is made of an inorganic insulating material. As the inorganic insulating layer has better performance in blocking water and oxygen compared to the organic insulating layer, the first pillar 121 being in the same layer as the inorganic insulating layer is favorable for blocking water and oxygen from entering the display region C from the opening region B.

The first isolation ring 122 is disposed in the same layer as one of the plurality of metal layers, such as the light-shielding layer 1301, the first gate layer 1302, the second gate layer 1303, or the third gate layer 1304.

In the case that the first isolation ring 122 is disposed in the same layer as the light-shielding layer 1301, the second isolation ring 123 is disposed in the same layer as one of the first semiconductor layer 1307, the first gate layer 1302, the second gate layer 1303, the second semiconductor layer 1308, the third gate layer 1304, the first source-drain layer 1305, and the second source-drain layer 1306, or is disposed in the same layer as the anode layer 141. The first pillar 121 is disposed in the same layer as one or more inorganic insulating layers, such as the buffer layer 1309, the first gate insulating layer 1310, the first insulating layer 1311, the second gate insulating layer 1312, the third gate insulating layer 1313, the interlayer dielectric layer 1314, or the passivation layer 1315, and the film layer in which the first pillar 121 is disposed is in the film layer in which the first isolation ring 122 is disposed and in the film layer in which the second isolation ring 123 is disposed.

In the case that the first isolation ring 122 is disposed in the same layer as the first gate layer 1302, the second isolation ring 123 is disposed in the same layer as one of the second gate layer 1303, the second semiconductor layer 1308, the third gate layer 1304, the first source-drain layer 1305, and the second source-drain layer 1306, or in the same layer as the anode layer 141. The first pillar 121 is disposed in the same layer as one or more inorganic insulating layers, such as the first insulating layer 1311, the second gate insulating layer 1312, the third gate insulating layer 1313, the interlayer dielectric layer 1314, or the passivation layer 1315, and the film layer in which the first pillar 121 is disposed is in the film layer in which the first isolation ring 122 is disposed and in the film layer in which the second isolation ring 123 is disposed.

In the case that the first isolation ring 122 is disposed in the same layer as the second gate layer 1303, the second isolation ring 123 is disposed in the same layer as one of the second semiconductor layer 1308, the third gate layer 1304, the first source-drain layer 1305, and the second source-drain layer 1306, or in the same layer as the anode layer 141. The first pillar 121 is disposed in the same layer as one or more inorganic insulating layers, such as the second gate insulating layer 1312, the third gate insulating layer 1313, the interlayer dielectric layer 1314, or the passivation layer 1315, and the film layer in which the first pillar 121 is disposed is in the film layer in which the first isolation ring 122 is disposed and in the film layer in which the second isolation ring 123 is disposed.

In the case that the first isolation ring 122 is in the same layer as the third gate layer 1304, the second isolation ring 123 is in the same layer as one of the first source-drain layer 1305 and the second source-drain layer 1306, or in the same layer as the anode layer 141. The first pillar 121 disposed in the same layer as one or more inorganic insulating layers, such as the interlayer dielectric layer 1314 or the passivation layer 1315, and the film layer in which the first pillar 121 is disposed is in the film layer in which the first isolation ring 122 is disposed and in the film layer in which the second isolation ring 123 is disposed.

Exemplarily, in the embodiments shown in FIG. 2, the light-emitting layer 14 further includes a pixel definition layer 142, a light-emitting layer 143, and a cathode layer 144 which are sequentially stacked on the side, away from the first surface C, of the anode layer 141. The display panel further includes a first inorganic encapsulation layer, a first organic encapsulation layer, a second inorganic encapsulation layer, a touch layer, a touch insulating layer, a touch organic protection layer, and a second organic encapsulation layer which are sequentially stacked on the side, away from the first surface C, of the light-emitting layer 14.

The touch layer is a self-compatible touch structure or a mutual-compatible touch structure, which is not limited in the present disclosure. The touch layer is provided based on requirements, and in the case that the display panel does not require a touch function, it is not required to provide the touch layer.

Exemplarily, the base substrate 11 is any transparent substrate, such as a glass substrate, a quartz substrate, a plastic substrate, another transparent rigid substrate, or another transparent flexible substrate, and the base substrate 11 has a single-layer or a multilayer structure. Taking the multilayer structure as an example, the base substrate 11 includes a first polyimide (PI) layer, a first protective layer, a second PI layer, and a second protective layer which are stacked from bottom to top. The two protective layers are configured to protect the PI layer and prevent damage to the PI layer in subsequent processes. The second protective layer is also covered by the buffer layer that blocks water oxygen and alkaline ions.

Exemplarily, the material for manufacturing the light-shielding layer 1301 is a metal material, including but not limited to molybdenum, aluminum, titanium, copper, and other materials. The light-shielding layer 1301 can reduce the light exposure to the thin film transistor (TFT) and can conduct electricity. The light-shielding layer 13 is also referred to as a bottom shield metal (BSM) layer.

Exemplarily, the first semiconductor layer 1307 is made of a low-temperature polysilicon material, and the second semiconductor layer 1308 is made of a metal oxide semiconductor material such as indium gallium zinc oxide (IGZO).

Optionally, the thickness of the second isolation ring 123 made of the low-temperature polysilicon material ranges from 400 μm to 600 μm.

Optionally, the thickness of the second isolation ring 123 made of IGZO ranges from 250 μm to 500 μm.

In the case that the metal layer in which the first isolation ring 122 is disposed is below the first semiconductor layer 1307 or the second semiconductor layer 1308, and the film layer in which the second isolation ring 123 is deposed is in the same layer as the first semiconductor layer 1307 or the second semiconductor layer 1308, because the thickness of the first semiconductor layer 1307 or the second semiconductor layer 1308 is less than the thickness of the metal layer below the first semiconductor layer 1307 or the second semiconductor layer 1308, the etching process of the first semiconductor layer 1307 or the second semiconductor layer 1308 has less effect on the metal layer where the first isolation ring 122 is disposed during the etching process.

Exemplarily, the materials for manufacturing the first gate insulating layer 1310, the first insulating layer 1311, the second gate insulating layer 1312, the third gate insulating layer 1313, the interlayer dielectric layer 1314, and the touch insulating layer are a silicon oxide or a silicon nitride, a silicon nitride oxide, or the like.

Exemplarily, the material for manufacturing the first gate layer 1302, the second gate layer 1303, and the third gate layer 1304 is a metal material, such as one or more of molybdenum, copper, aluminum, or one or more of titanium and aluminum.

Exemplarily, the material for manufacturing the passivation layer 1315 is a silicon oxide layer, a silicon nitride layer, or a silicon oxide layer.

Exemplarily, the first planarization layer 1316 and the second planarization layer 137 are made of an organic insulating material, such as resin.

Exemplarily, the anode layer 141 is made of a metal material, such as gold or silver, or the anode layer 141 is made of a transparent conductive material, such as indium tin oxide (ITO).

Exemplarily, the material for manufacturing the pixel definition layer 142 includes one or more of polyimide, polyphthalimide, polyamide, silicon oxide, silicon nitride, and the like.

Exemplarily, the light-emitting layer 143 may include a hole transport layer (HTL), a hole injection layer (HIL), an electron transport layer (ETL), an electron injection layer, EIL), a hole block layer (HBL), an electron blocking layer (EBL), and a light-emitting material layer.

Exemplarily, the cathode layer 144 is made of a metal material such as a magnesium-silver alloy, or is made of a transparent conductive material such as ITO.

Exemplarily, the first inorganic encapsulation layer and the second inorganic encapsulation layer are made of silicon nitride, silicon oxide, or silicon nitride oxide material. The first organic encapsulation layer and the second organic encapsulation layer are made of an organic insulating material, and the organic insulating material includes a material such as polyimide, polyamide, acrylic resin, benzocyclobutene, hexamethyldisiloxane (HMDSO), phenolic resin, and the like.

Exemplarily, the touch organic protective layer is made of an organic material that can be heat-cured or light-cured, such as an acrylate, an epoxy resin, and the like. The touch organic protective layer is also referred to as a touch organic coating (TOC) layer.

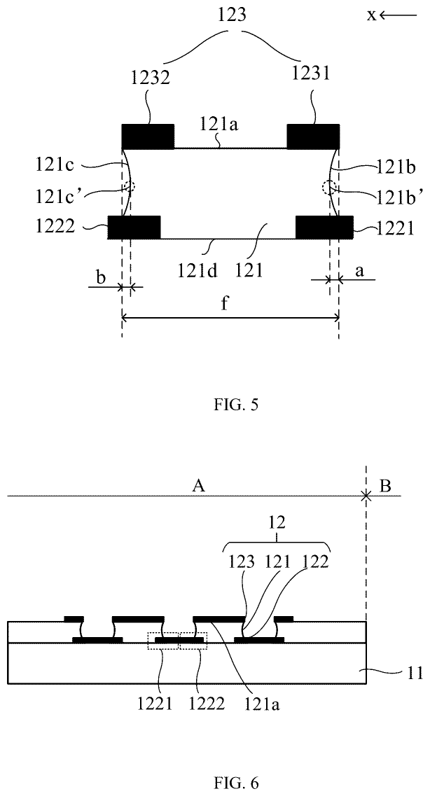

FIG. 5 is a schematic diagram of a structure of another isolation pillar according to some embodiments of the present disclosure. The difference between the structure of the isolation pillar shown in FIG. 5 and the structure of the isolation pillar shown in FIG. 3 is the different structure of the second isolation ring 123.

As shown in FIG. 5, the second isolation ring 123 includes a third subring 1231 and a fourth subring 1232 which are sequentially arranged in a radially outward direction x centered on the center of the opening region B. The third subring 1231 is disposed at an edge, close to the first sidewall 121b, of the first top surface 121a, and the fourth subring 1232 is disposed at an edge, close to the second sidewall 121c, of the first top surface 121a. The internally disconnected second isolation ring 123 facilitates blocking electrical signals from passing through the isolation pillar 12.

FIG. 6 is a schematic diagram of a structure of another isolation pillar according to some embodiments of the present disclosure. The difference between the structure of the isolation pillar shown in FIG. 6 and the structure of the isolation pillar shown in FIG. 3 is that in the two adjacent isolation pillars 12, the first subring 1221, away from the opening region B, of the isolation pillar 12 is connected to the second subring 1222, close to the opening region B, of the isolation pillar 12 to form an integrated structure.

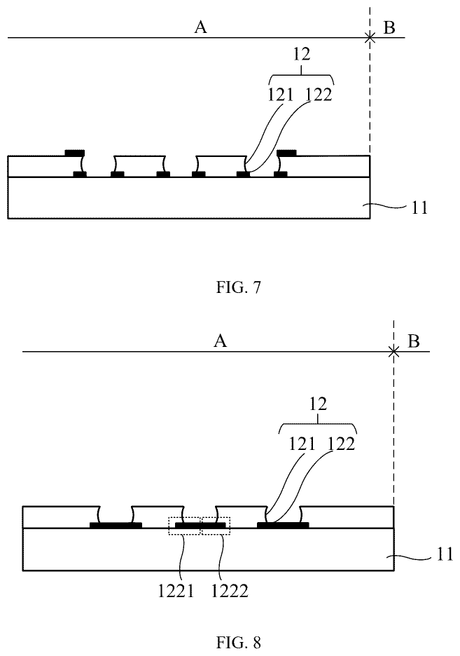

In the embodiments shown in FIGS. 7 and 8, the isolation pillar 12 includes only the first pillar 12 and the first isolation ring 122 without the second isolation ring 123.

It is noted that in other embodiments, the isolation pillar 12 includes the first pillar 12 and the second isolation ring 123 without including the first isolation ring 122.

FIG. 9 is a schematic diagram of a structure of another isolation pillar according to some embodiments of the present disclosure. The difference between the isolation pillar shown in FIG. 9 and the isolation pillar shown in FIG. 5 is that the second isolation ring 123 is disposed in the same layer as the first semiconductor layer 1307 or the second semiconductor layer 1308.

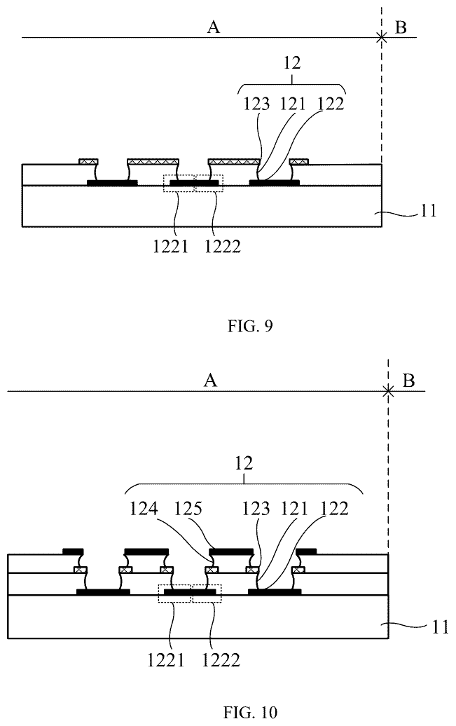

FIG. 10 is a schematic diagram of a cross-sectional structure close to an opening region of another display panel according to some embodiments of the present disclosure. As shown in FIG. 10, the isolation pillar 12 includes a first isolation ring 122, a second isolation ring 123, and a second pillar 124. The structures of the first pillar 121, the first isolation ring 122, and the second isolation ring 123 are the same as the structures in the embodiments shown in FIG. 3, which are not repeated herein. The second pillar 124 is disposed on a side, away from the first surface C, of the second isolation ring 123. The second pillar 124 is made of an insulating material.

Arranging the isolation pillar to have a multi-layer structure is conducive to increasing the height of the isolation pillar and enhancing the isolation performance of the isolation pillar. The second pillar is also made of an insulating material, which is conducive to further blocking the transmission of electrical signals from the display region to the vicinity of the opening region.

Optionally, in the case that the isolation pillar 12 includes a first pillar 121 and a second pillar 124:
the first isolation ring 122 is disposed in the same layer as one of the plurality of metal layers, such as the light-shielding layer 1301, the first gate layer 1302, the second gate layer 1303, or the third gate layer 1304.

In the case that the first isolation ring 122 is disposed in the same layer as the light-shielding layer 1301, the second isolation ring 123 is disposed in the same layer as one of the first semiconductor layer 1307, the first gate layer 1302, the second gate layer 1303, the second semiconductor layer 1308, the third gate layer 1304, the first source-drain layer 1305, and the second source-drain layer 1306. The third isolation ring 125 is disposed in the same layer as one of the first gate layer 1302, the second gate layer 1303, the second semiconductor layer 1308, the third gate layer 1304, the first source-drain layer 1305, and the second source-drain layer 1306, or in the same layer as the anode layer 141, and the film layer in which the third isolation ring 125 is disposed is on the side, away from the first surface C, of the film layer in which the second isolation ring 123 is disposed.

In the case that the first isolation ring 122 is disposed in the same layer as the first gate layer 1302, the second isolation ring 123 is disposed in the same layer as one of the second gate layer 1303, the second semiconductor layer 1308, the third gate layer 1304, the first source-drain layer 1305, and the second source-drain layer 1306. The third isolation ring 125 is disposed in the same layer as one of the second semiconductor layer 1308, the third gate layer 1304, the first source-drain layer 1305, and the second source-drain layer 1306, or in the same layer as the anode layer 141, and the film layer in which the third isolation ring 125 is disposed is on the side, away from the first surface C, of the film layer in which the second isolation ring 123 is disposed.

In the case that the first isolation ring 122 is disposed in the same layer as the second gate layer 1303, the second isolation ring 123 is disposed in the same layer as one of the second semiconductor layer 1308, the third gate layer 1304, the first source-drain layer 1305, and the second source-drain layer 1306. The third isolation ring 125 is disposed in the same layer as one of the third gate layer 1304, the first source-drain layer 1305, and the second source-drain layer 1306, or is in the same layer as the anode layer 141, and the film layer in which the third isolation ring 125 is disposed is on a side, away from the first surface C, of the film layer in which the second isolation ring 123 is disposed.

In the case that the first isolation ring 122 is disposed in the same layer as the third gate layer 1304, the second isolation ring 123 is disposed in the same layer as one of the first source-drain layer 1305 and the second source-drain layer 1306. The third isolation ring 125 is disposed in the same layer as one of the third gate layer 1304, the first source-drain layer 1305, and the second source-drain layer 1306, or in the same layer as the anode layer 141, and the film layer in which the third isolation ring 125 is disposed is on the side, away from the first surface C, of the film layer in which the second isolation ring 123 is disposed.

The first pillar 121 is disposed in the same layer as one or more inorganic insulating layers, such as the buffer layer 1309, the first gate insulating layer 1310, the first insulating layer 1311, the second gate insulating layer 1312, the third gate insulating layer 1313, the interlayer dielectric layer 1314, or the passivation layer 1315, and the film layer in which the first pillar 121 is disposed is the film layer in which the first isolation ring 122 is disposed and in the film layer in which the second isolation ring 123 is disposed. The second pillar 124 is disposed in the same layer as one or more insulating layers, such as the first gate insulating layer 1310, the first insulating layer 1311, the second gate insulating layer 1312, the third gate insulating layer 1313, the interlayer dielectric layer 1314, the passivation layer 1315, the first planarization layer 1316, or the second planarization layer 1317, and the film layer in which the second pillar 124 is disposed is in the film layer in which the second isolation ring 123 is disposed and in the film layer in which the third isolation ring 122 is disposed.

FIG. 11 is a schematic diagram of a cross-sectional structure of an isolation pillar according to some embodiments of the present disclosure, and FIG. 11 is a partially enlarged view of the isolation pillar 12 in FIG. 10. As shown in FIG. 10, the second pillar 124 has a second bottom surface 124d close to the first surface C, a second top surface 124a away from the first surface, and a third sidewall 124b and a fourth sidewall 124c between the second top surface 124a and the second bottom surface 124d. The third sidewall 124b is close to the opening region B and is recessed in a direction away from the opening region B. The fourth sidewall 124c is away from the opening region B and is recessed in a direction close to the opening region B. In this way, the I-shaped structure is formed, which is conducive to naturally isolating the film layer on the isolation pillar 12 and simplifying the process of manufacturing the display panel.

Optionally, in the radial direction x of the opening region B, the distance between the edge, close to the opening region B, of the orthographic projection of the second top surface 124a on the first surface and the contour line, away from the opening region B, of the orthographic projection of the third sidewall 124c on the first surface C ranges from 0.1 μm to 2.0 μm. That is, the third recessed line ring 124b′ that is farthest away from the opening region B is disposed on the third sidewall 124b. The distance c between the projection of the third recessed line ring 124b′ on the first surface C and the edge, close to the opening region B, of the orthographic projection of the second top surface 124b on the first surface C ranges from 0.1 μm to 2.0 μm. The recess having the range of dimension enables the I-shaped structure to have a better isolation effect. The larger dimension of the recess affects the support ability of the second pillar 124, and a smaller dimension of the recess causes the I-shape less obvious and affects the isolation effect.

In the radial direction x of the opening region B, the distance between the edge, away from the opening region B, of the orthographic projection of the second top surface 124a on the first surface C and the contour line, close to the opening region B, of the orthographic projection of the fourth sidewall 124c on the first surface C ranges from μm 0.1 to 2.0 μm. That is, the fourth recess line ring 124c′ that is closest to the opening region B is disposed on the fourth sidewall 124c. The distance d between the projection of the fourth recess line ring 124c′ on the first surface C and the edge, away from the opening region B, of the orthographic projection of the second top surface 124a on the first surface C ranges from 0.1 μm to 2.0 μm. The recess having the range of dimension enables the I-shaped structure to have a better isolation effect. The larger dimension of the recess affects the support ability of the second pillar 124, and a smaller dimension of the recess causes the I-shape less obvious and affects the isolation effect.

Exemplarily, as shown in FIG. 11, the radial width e of the second top surface 124a is less than the radial width f of the first top surface 121a. In conjunction with FIG. 3, the design that e is less than f causes the gap between adjacent isolation pillars 12 in the middle portion larger than the gap in the upper portion, facilitating the vapor deposition of the first inorganic encapsulation layer in the subsequent process, which causes the first inorganic encapsulation layer material to cover the top surface and the sidewalls of the isolation pillar 12 and results in good encapsulation effect.

In other possible embodiments, the radial width e of the second top surface 124a is equal to the radial width f of the first top surface 121a. The design that e is equal to f also causes the first inorganic encapsulation layer material to be better deposited onto the top surface and the sidewalls of the isolation pillar 12 in the subsequent process, which results in a good encapsulation effect.

Exemplarily, in conjunction with FIGS. 10 and 11, the dimension of the second top surface 124a ranges from 3 μm to 10 μm in the radial direction away from the opening region B, and the distance between the second top surfaces of two adjacent second pillars 124 ranges from 5 μm to 20 μm. The radial dimension of the second top surface 124a represents the size of the isolation pillar 12 in the case that the isolation pillar 12 includes the first pillar 121 and the second pillar 124. The spacing in the radial direction of two adjacent second top surfaces 124a represents the distance between two adjacent isolation pillars 12, and the isolation pillar 12 having this dimension is not too narrow for poor support, nor too wide for unfavorable narrow bezel design.

Exemplarily, as shown in FIG. 11, the radial dimension g of the overlapping region of the first subring 1221 with the third subring 1231 ranges from 3 μm to 10 μm, and the radial dimension h of the overlapping region of the second subring 1222 with the fourth subring 1232 ranges from 3 μm to 10 μm. Optionally, g ranges from 6 μm to 10 μm, and h ranges from 6 μm to 10 μm.

Exemplarily, as shown in FIG. 11, the radial dimension of the overlapping region of the third subring 1231 with the third isolation ring 125 ranges from 3 μm to 10 μm. Optionally, the radial dimension of the overlapping region of the third subring 1231 with the third isolation ring 125 ranges from 6 μm to 10 μm.

Exemplarily, as shown in FIG. 11, the radial dimension of the overlapping region of the fourth subring 1232 with the third isolation ring 125 ranges from 3 μm to 10 μm. Optionally, the radial dimension of the overlapping region of the fourth subring 1232 with the third isolation ring 125 ranges from 6 μm to 10 μm.

Optionally, for the isolation pillar further including the second pillar 124, the dimension e of the second top surface 124a ranges from 3 μm to 10 μm in the radial direction x of the opening region B.

Optionally, in the radial direction x of the opening region B, the distance between the first top surfaces 121a of two adjacent first pillars 121 ranges from 5 μm to 20 μm.

Optionally, exemplarily, in conjunction with FIGS. 10 and 11, the isolation pillar 12 further includes a third isolation ring 125, and the third isolation ring 125 is disposed on a side, away from the first surface C, of the second pillar 124 and is made of a non-insulating material. The third isolation ring 125 facilitates the formation of the second pillar 124 having an I-shaped structure to enhance the isolation effect.

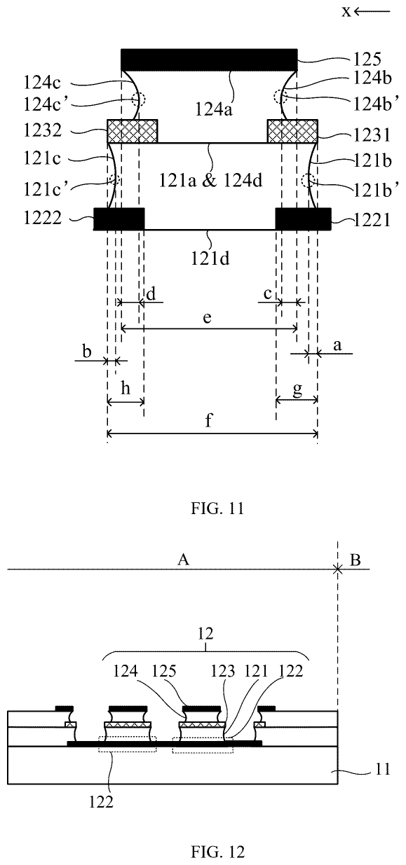

FIG. 12 is a schematic diagram of a cross-sectional structure in a vicinity of an opening region of another display panel according to some embodiments of the present disclosure. Compared to the embodiments shown in FIG. 10, in the embodiments shown in FIG. 12, for two adjacent isolation pillars 12, a plurality of first isolation rings 122 of the isolation pillars 12 away from the opening region B are connected to form an integrated structure. The second isolation ring 123 is an integrated structure.

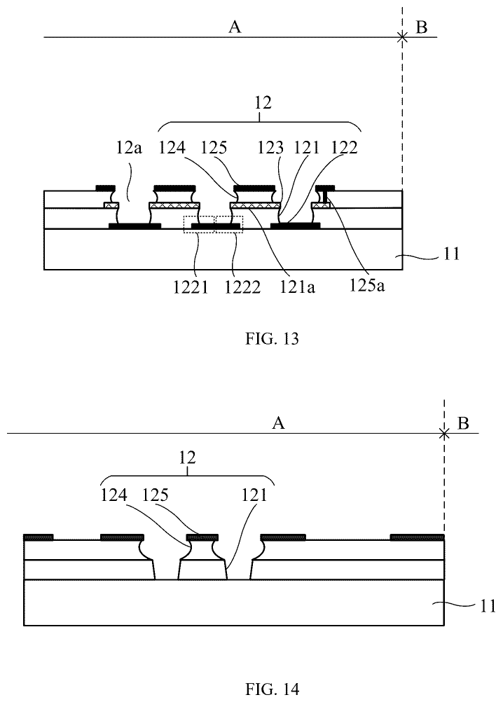

FIG. 13 is a schematic diagram of a cross-sectional structure in a vicinity of an opening region of another display panel according to some embodiments of the present disclosure. Compared to the embodiments shown in FIG. 10, in the embodiments shown in FIG. 13, the second isolation ring 123 is an integrated structure and covers the first top surface 121a.

Optionally, the display panel further includes at least one block wall. The at least one block wall is disposed in the film layer in which the second pillar 124 is disposed and is connected to the film layer in which the second isolation ring 123 is disposed and to the film layer in which the third isolation ring 125 is disposed.

Exemplarily, as shown in FIG. 13, the block wall in the display panel is a first block wall 125a, and the first block wall 125a is disposed on the side, close to the opening region B, of the first isolation groove. The first isolation groove is the isolation groove 12a closest to the opening region among the plurality of isolation grooves 12a, and the first block wall 125a is disposed in the film layer in which the second pillar 124 is disposed and is connected to the film layer in which the second isolation ring 123 is disposed and to the film layer in which the third isolation ring 125 is disposed. The block wall 125a is configured to prevent water and oxygen from entering the display region.

Optionally, the second pillar 124 is made of an organic insulating material. As the organic insulating material can absorb water and oxygen, the solution of providing the block wall 125a is particularly suitable for the second pillar 124 made of the organic insulating material.

In another possible embodiment, the display panel includes at least one second block wall, and each of the second block walls is disposed in the second pillar 124 of one isolation pillar 12.

For example, the display panel includes one second block wall that is disposed in the second pillar 124 of one of the plurality of isolation pillars 12 that is closest to the opening region B and is connected to the second isolation ring 123 and the third isolation ring 125 of the isolation pillar 12. In this manner of designing the block wall to be disposed in the isolation pillars 12, the block wall 125a may also be configured to prevent water and oxygen from entering the display region.

In yet another possible embodiment, the display panel may also include a first block wall and at least one second block wall.

Alternatively, in other embodiments, the block wall may also pass through a plurality of insulating layers, for example, the second pillar 124 and the first pillar 121. The block wall connects the third isolation ring 125 to the first isolation ring 121, or passes through the second pillar 124 and at least part of the first pillar 121 and connects the second isolation ring 123 to the first isolation ring 121.

Optionally, the material of the block wall is the same as the third isolation ring material, or other non-organic insulating material in the driving circuit.

FIG. 14 is a schematic diagram of a cross-sectional structure in a vicinity of an opening region of another display panel according to some embodiments of the present disclosure. Compared to the embodiments shown in FIG. 10, in the embodiments shown in FIG. 14, the isolation pillar 12 includes a first pillar 121, a second pillar 124, and a third isolation ring 125, but does not include a first isolation ring 122 and a second isolation ring 123, and the first sidewall 121b and the second sidewall 121c are planar surfaces. An acute angle is between the planar surface and the first surface. The first pillar 121 having the first sidewall 121b and the second sidewall 121c as planar surfaces also has the function to support the second pillar 124, facilitating the second pillar 124 to isolate the upper film layers.

Optionally, in the embodiments shown in FIG. 14, the second pillar 124 is disposed in the same layer as an organic insulating layer of the plurality of insulating layers, such as the first planarization layer 1316 and the second planarization layer 1317. As the second pillar 124 is made of organic insulating material in the embodiments shown in FIG. 14, the above block wall is also provided to block water and oxygen.

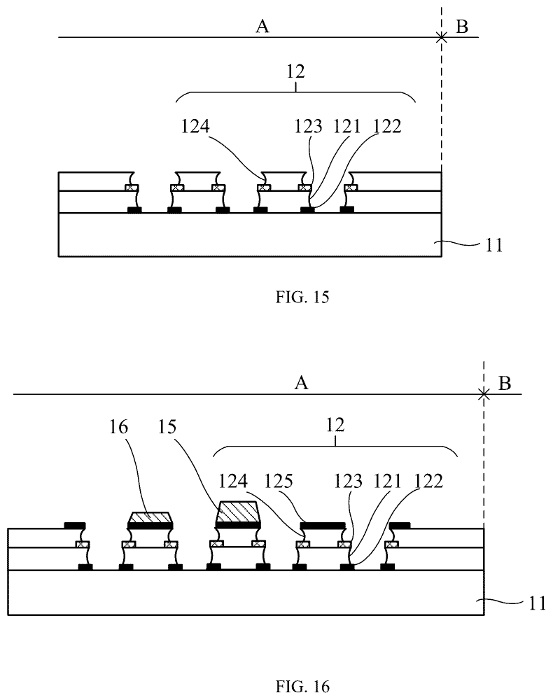

In the embodiments shown in FIG. 15, the isolation pillar 12 includes a first pillar 121, a first isolation ring 122, a second isolation ring 123, and a second pillar 124, but does not include a third isolation ring 125.

Optionally, for the isolation pillar 12 that does not include the second pillar 124, the height of the isolation pillar 12 ranges from 0.1 μm to 1.5 μm. For the isolation pillar 12 which includes the second pillar 124 made of an inorganic insulating material, the height of the isolation pillar 12 ranges from 0.2 μm to 2.0 μm. For the isolation pillar 12 which includes the second pillar 124 made of an organic insulating material, the height of the isolation pillar 12 ranges from 0.6 μm to 6.0 μm.

Exemplarily, referring again to FIG. 2, the display panel further includes a dam structure 15, the dam structure 15 is disposed on a surface, away from the first surface C, of one of the isolation pillars 12. The dam structure 15 surrounds the opening region. The dam structure 15 prevents organic material, such as organic encapsulation material, from spilling into the opening region B. The design of one dam structure 15 facilitates application in narrow bezel products. In other possible embodiments, the display panel includes a plurality of dam structures 15.

FIG. 16 is a schematic diagram of a cross-sectional structure in a vicinity of an opening region of another display panel according to some embodiments of the present disclosure. As shown in FIG. 16, the display panel further includes a block ring 16, the block ring 16 is disposed on a surface, away from the first surface, of one of the plurality of isolation pillars 12, and the block ring 16 surrounds the dam structure 15. In a direction perpendicular to the first surface C, the dimension of the block ring 16 is less than the dimension of the dam structure 15. That is, the height of the block ring 16 is less than the height of the dam structure 15. The block ring 16 is configured to block the flow of organic material (e.g., organic encapsulated material), and prevent the organic material from spilling out and overtopping the dam structure 15.

Optionally, the block ring 16 is disposed in the same layer as one of the first planarization layer 1316, the second planarization layer 1317, the pixel definition layer 142, or a film layer made of an organic insulating material such as a spacer, wherein the spacer is configured to support a fine metal mask (FMM) used to evaporation deposit the light-emitting layer material when forming the light-emitting layer 143.

FIG. 17 is a schematic diagram of a cross-sectional structure in a vicinity of an opening region of another display panel according to some embodiments of the present disclosure. As shown in FIG. 17, the plurality of isolation pillars 12 includes a plurality of outer isolation pillars and a plurality of inner isolation pillars, the plurality of outer isolation pillars are disposed on a side, close to the opening region B, of the dam structure 15, and the plurality of inner isolation pillars C are disposed on a side, away from the opening region B, of the dam structure 15. A groove is disposed on a surface, away from the first surface C, of at least one outer isolation pillar of the plurality of outer isolation pillars. The display panel further includes a filling structure 17 disposed in the groove.

Optionally, as shown in FIG. 17, at least a portion of the isolation pillar 12 is made of an inorganic insulating material, and at least a portion of the groove is disposed in the portion of the isolation pillar 12 made of the inorganic insulating material.

In other possible embodiments, the isolation pillar 12 does not include a first pillar 121 and the groove passes through a portion of the first pillar 121. In other possible embodiments, the isolation pillar 12 includes a first pillar 121 and a second pillar 124, the second pillar 124 is made of an organic insulating material, and the groove passes through a portion of the second pillar 124 and a portion of the first pillar 121. In other possible embodiments, the isolation pillar 12 includes a first pillar 121 and a second pillar 124, both the first pillar and the second pillar are made of an inorganic insulating material, and the groove passes through a portion of the second pillar 124 or passes through the second pillar 124 and the first pillar 121.

The filling structure 17 disposed in the groove is made of an organic insulating material. In this way, the filling structure 17 made of the organic insulating material can be used in conjunction with the first pillar 121 made of the inorganic insulating material, or the first pillar 121 and the second pillar 124 supported by the inorganic insulating material, to enhance the mechanical impact resistance of the border of the opening region B.

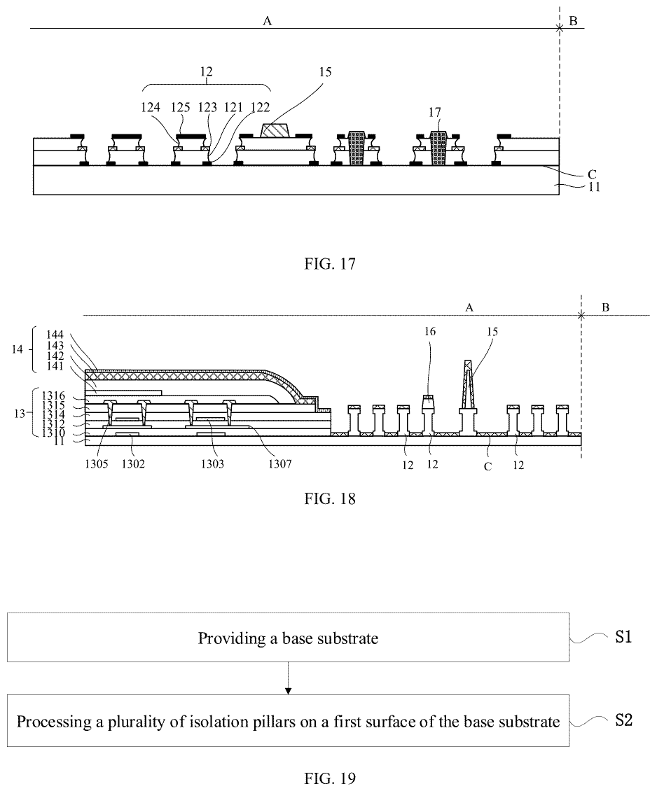

FIG. 18 is a schematic diagram of a cross-sectional structure of another display panel according to some embodiments of the present disclosure. As shown in FIG. 18, the difference compared to the embodiments shown in FIG. 2 is that the type of the driving backplane is different. In FIG. 18, the driving backplane is a low-temperature poly-silicon (LTPS) backplane.

For the LTPS backplane, the plurality of metal layers of the driving circuit layer include a first gate layer 1302, a second gate layer 1303, and a first source-drain layer 1305 which are sequentially stacked on a first surface. The driving circuit layer 13 includes one semiconductor layer, i.e., a first semiconductor layer 1307, and the first semiconductor layer 1307 is disposed between the first gate layer 1302 and the second gate layer 1303.

The plurality of insulating layers includes a first gate insulating layer 1310, a first insulating layer 1311, a second gate insulating layer 1312, an interlayer dielectric layer 1314, a passivation layer 1315, a first planarization layer 1316, and a second planarization layer 1317.

The first gate layer 1302, the first gate insulating layer 1310, the first semiconductor layer 1307, the second gate insulating layer 1312, the second gate layer 1303, the interlayer dielectric layer 1314, the passivation layer 1315, the first source-drain layer 1305, and the first planarization layer 1316 are sequentially stacked on the first surface C.

The layer structures of the isolation pillar are flexibly selected based on the requirements, such as the height of the isolation pillar, to be co-layered with which film layer of the driving backplane.

Exemplarily, as shown in FIG. 17, the display panel further includes a light-emitting layer 14 disposed on the driving backplane, and the light-emitting layer 14 includes an anode layer 141. The display panel further includes a first inorganic encapsulation layer, a first organic encapsulation layer, a second inorganic encapsulation layer, a touch layer, a touch insulating layer, a touch organic protection layer, and a second organic encapsulation layer which are sequentially stacked on the side, away from the first surface C, of the light-emitting layer 14. The layered relationship and the materials for manufacturing are the same as those in the previous LTPO backplane section, which are not repeated herein.

In some possible embodiments, the isolation pillar 12 includes a first pillar 121, but does not include a second pillar 124:

the first isolation ring 122 is disposed in the same layer as one of the plurality of metal layers, such as the first gate layer 1302 or the second gate layer 1303.

In the case that the first isolation ring 122 is disposed in the same layer as the first gate layer 1302, the second isolation ring 123 is disposed in the same layer as one of the first semiconductor layer 1307, the second gate layer 1303, and the first source-drain layer 1305, or disposed in the same layer as the anode layer 141. The first pillar 121 is disposed in the same layer as one or more inorganic insulating layers, e.g., the first gate insulating layer 1310, the second gate insulating layer 1312, the interlayer dielectric layer 1314, or the passivation layer 1315, and the film layer in which the first pillar 121 is disposed is in the film layer in which the first isolation ring 122 is disposed and in the film layer in which the second isolation ring 123 is disposed.

In the case that the first isolation ring 122 is disposed in the same layer as the second gate layer 1303, the second isolation ring 123 is in the same layer as the first source-drain layer 1305 or in the same layer as the anode layer 141. The first pillar 121 is disposed in the same layer as one or more inorganic insulating layers, e.g., interlayer dielectric layer 1314 or passivation layer 1315, and the film layer in which the first pillar 121 is disposed is in the film layer in which the first isolation ring 122 is disposed and in the film layer in which the second isolation ring 123 is disposed.

In other possible embodiments, in the case that the isolation pillar 12 includes a first pillar 121 and a second pillar 124:

the first isolation ring 122 is disposed in the same layer as one of the plurality of metal layers, such as the first gate layer 1302 or the second gate layer 1303.

In the case that the first isolation ring 122 is disposed in the same layer as the first gate layer 1302, the second isolation ring 123 is disposed in the same layer as one of the first semiconductor layer 1307, the second gate layer 1303, and the first source-drain layer 1305. The third isolation ring 125 is disposed in the same layer as one of the second gate layer 1303 and the first source-drain layer 1305, or in the same layer as the anode layer 141, and the film layer in which the third isolation ring 125 is disposed is on a side, away from the first surface C, of the film layer on which the second isolation ring 123 is disposed. The first pillar 121 is disposed in the same layer as one or more inorganic insulating layers, e.g., the first gate insulating layer 1310, the second gate insulating layer 1312, the interlayer dielectric layer 1314, or the passivation layer 1315, and the film layer in which the first pillar 121 is disposed is in the film layer in which the first isolation ring 122 is disposed and in the film layer in which the second isolation ring 123 is disposed. The second pillar 125 is disposed in the same layer as one or more insulating layers, e.g., the second gate insulating layer 1312, the interlayer dielectric layer 1314, the passivation layer 1315, and the first planarization layer 1316, and the film layer in which the second pillar 125 is disposed is in the film layer in which the second isolation ring 123 is disposed and in the film layer in which the third isolation ring 125 is disposed. In the case that the first isolation ring 122 is disposed in the same layer as the second gate layer 1303, the second isolation ring 123 is disposed in the same layer as the first source-drain layer 1305. The third isolation ring 125 is disposed in the same layer as the anode layer 141. The first pillar 121 is disposed in the same layer as one or more of the interlayer dielectric layer 1314 and the passivation layer 1315. The second pillar 124 is disposed in the same layer as the first planarization layer 1316.

FIG. 19 is a flowchart of a method for manufacturing a display panel according to some embodiments of the present disclosure, as shown in FIG. 19, the method includes the following steps.

In step S1, a base substrate is provided, wherein the base substrate includes an opening region and a display region, and the display region surrounds the opening region.

In step S2, a plurality of isolation pillars are processed on a first surface of the base substrate.

The plurality of isolation pillars are circular and surround the opening region, each of the plurality of isolation pillars includes a first pillar made of an insulating material, wherein an isolation groove surrounding the opening region is disposed at both sides of the first pillar, the first pillar has a first top surface away from the first surface, a first bottom surface close to the first surface, and a first sidewall and a second sidewall between the first top surface and the first bottom surface.

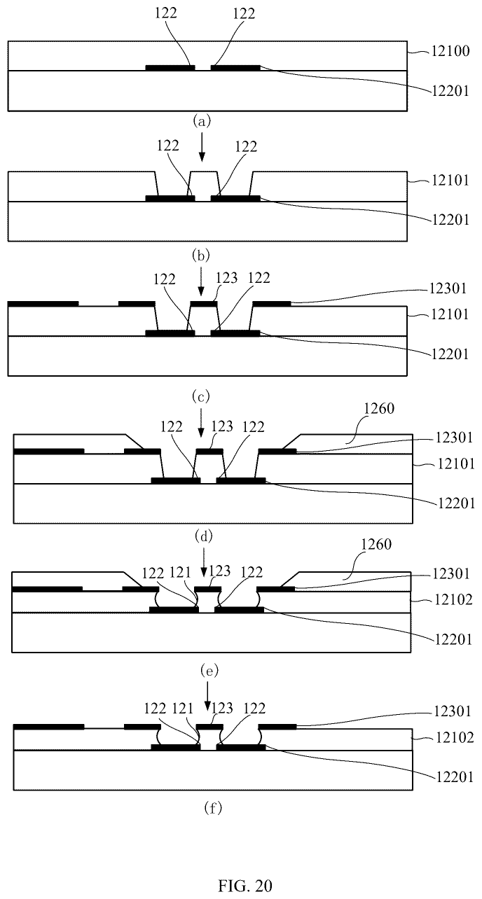

FIG. 20 is a schematic diagram of a flow of processing another isolation pillar according to some embodiments of the present disclosure, which can be applied to process the isolation pillar as shown in FIG. 3. The flow of processing includes the following steps.

In a first step, as shown in part (a) of FIG. 20, a first initialization film layer is formed by deposition or the like, and the first initialization film layer is patterned to acquire a first patterned film layer 12201. A second initialization film layer 12100 is formed on the first patterned film layer 12201. The first patterned film layer 12201 includes a first isolation ring 122. Exemplarily, the first patterned film layer 12201 further includes one of a light-shielding layer, a first gate layer, a second gate layer, and the like in the LTPO backplane, and the structures are described in detail in the previous description, which are not repeated herein.

In a second step, as shown in part (b) of FIG. 20, the second initialization film layer 12100 is patterned to acquire a second patterned film layer 12101, and grooves exposing a portion of the first patterned film layer 12201 are disposed in the second patterned film layer 12101.

In a third step, as shown in part (c) of FIG. 20, a third initialization film layer is acquired by deposition or the like on the second patterned film layer 12101, and the third initialization film layer is patterned to acquire a third patterned film layer 12301, and the third patterned film layer 12301 includes a second isolation ring 123. Exemplarily, the third film layer 1230 is made of a metal material. Optionally, the third patterned film layer 12301 is made of a metal material.

In a fourth step, as shown in part (d) of FIG. 20, the photoresist structure 1260 is acquired by a process of photoresist coating, exposure, and development on a side, away from the first patterned film layer 12201, of the third patterned film layer 12301.

In a fifth step, as shown in part (e) of FIG. 20, the photoresist structure 1260 is used as a mask, and the second film layer 12102 is acquired by etching the openings of the second patterned film layer 12101 by, for example, a dry-etching method. The second film layer 12102 includes a plurality of first pillars 121 having an I-shaped structure, and each of the first patterned film layer 12201 below the I-shaped structure has two ring structures.

Optionally, the etching rate of the second patterned film layer 12101 is greater than the etching rate of the third patterned film layer 12301, such that it can be ensured that the third patterned film layer 12301 is retained upon etching the second patterned film layer 12101. At the same time, in the case that the second patterned film layer 12101 is etched, the etching rate of the second patterned film layer 12101 is also greater than the etching rate of the first patterned film layer 12201, and thus the I-shaped structure can be formed on the second patterned film layer 12101.

In a sixth step, as shown in part (f) of FIG. 20, the photoresist structure 1260 is removed by a stripping process to acquire the isolation pillar as shown in FIG. 3.

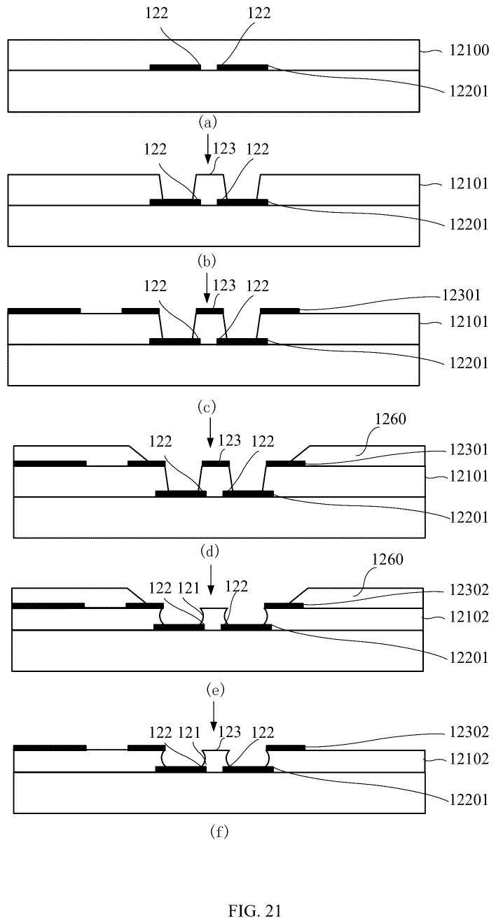

FIG. 21 is a schematic diagram of a flow of processing an isolation pillar according to some embodiments of the present disclosure, which can be applied to process the isolation pillar as shown in FIG. 8. The difference compared to the process shown in FIG. 20 is as follows.

In a fifth step, as shown in part (e) of FIG. 21, the photoresist structure 1260 is used as a mask, and the second film layer 12102 is acquired by etching the grooves of the second patterned film layer 12101 by, for example, a dry-etching method. The second film layer 12102 includes a plurality of first pillars 121 having an I-shaped structure, and each of the first patterned film layer 12201 below the I-shaped structure has two ring structures. At the same time, a third film layer 12302 is also acquired by removing a portion of the third patterned film layer 12301 by etching.

In a sixth step, as shown in part (f) of FIG. 21, the photoresist structure 1260 is removed by a stripping process to acquire the isolation pillar as shown in FIG. 8.

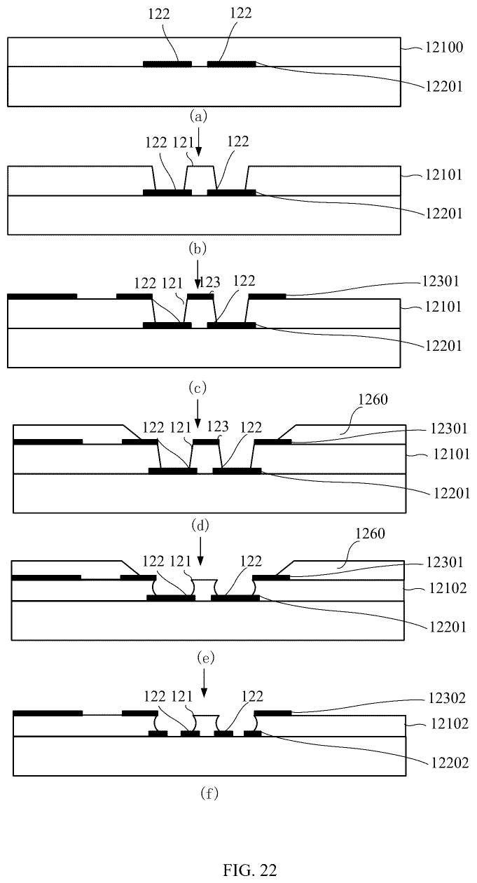

FIG. 22 is a schematic diagram of a flow of processing another isolation pillar according to some embodiments of the present disclosure, which is applied to process the isolation pillar as shown in FIG. 7. The difference compared to the process shown in FIG. 20 is as follows.

In a fifth step, as shown in part (e) of FIG. 22, the photoresist structure 1260 is used as a mask, and the second film layer 12102 is acquired by etching the grooves of the second patterned film layer 12101 by, for example, a dry-etching method. The second film layer 12102 includes a plurality of first pillars 121 having an I-shaped structure, and each of the first patterned film layer 12201 below the I-shaped structure has two ring structures.

In a sixth step, as shown in part (f) of FIG. 22, a third film layer 12302 is acquired by removing a portion of the third patterned film layer 12301 by etching, and a first film layer 12202 is acquired by removing a portion of the first patterned film layer 12201 by etching. The photoresist structure 1260 is removed by a stripping process to acquire the isolation pillar as shown in FIG. 7.

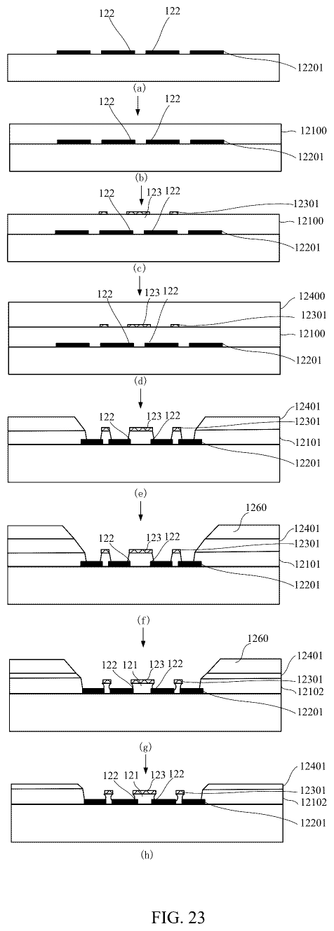

FIG. 23 is a schematic diagram of a flow of processing another isolation pillar according to some embodiments of the present disclosure, which is applied to process the isolation pillar as shown in FIG. 9. The flow of processing includes the following steps.

In a first step, as shown in part (a) of FIG. 23, a first initialization film layer is formed by deposition or the like, and the first initialization film layer is patterned to acquire a first patterned film layer 12201. The first patterned film layer 12201 includes a first isolation ring 122. Exemplarily, the first patterned film layer 12201 further includes one of a light-shielding layer, a first gate layer, a second gate layer, and the like in the LTPO backplane, and the structures are described in detail in the previous description, which are not repeated herein.

In a second step, as shown in part (b) of FIG. 23, a second initialization film layer 12100 is formed on the first patterned film layer 12201.

In a third step, as shown in part (c) of FIG. 23, a third initialization film layer is acquired by depositing on the second initialization film layer 12100, and the third initialization film is patterned to acquire the third patterned film layer 12301. Optionally, the third patterned film layer is made of a semiconductor material.

In a fourth step, as shown in part (d) of FIG. 23, a fourth initialization film layer 12400 is formed by depositing on the third patterned film layer 12301.

In a fifth step, as shown in part (e) of FIG. 23, the fourth initialization film layer 12400 and the second initialization film layer 12100 are patterned to acquire the fourth patterned film layer 12401 and the second patterned film layer 12101.

In a sixth step, as shown in part (f) of FIG. 23, the photoresist structure 1260 is acquired by a process of photoresist coating, exposure, and development on a side, away from the first patterned film layer 12201, of the fourth patterned film layer 12401.

In a seventh step, as shown in part (g) of FIG. 23, the photoresist structure 1260 is used as a mask, and the second film layer 12102 is acquired by etching the openings of the second patterned film layer 12101 by, for example, a dry-etching method. The second film layer 12102 includes a plurality of I-shaped structures. Each of the first patterned film layer 12201 below the I-shaped structure has two ring structures. Optionally, in the etching process of the second patterned film layer 12101, the third patterned film layer 12301 made of the semiconductor material is equivalent to a template, and the first patterned film layer 12201 made of the metal material is equivalent to a substrate. As the etching rate of the inorganic insulating material is greater than the etching rate of the metal and semiconductor materials, that is, the etching rate of the etched layer is greater than the etching rate of the template and substrate, an I-shaped structure is formed in the second patterned film layer 12101 upon etching.

In an eighth step, as shown in part (h) of FIG. 23, the photoresist structure 1260 is removed by a stripping process to acquire the isolation pillar as shown in FIG. 9.

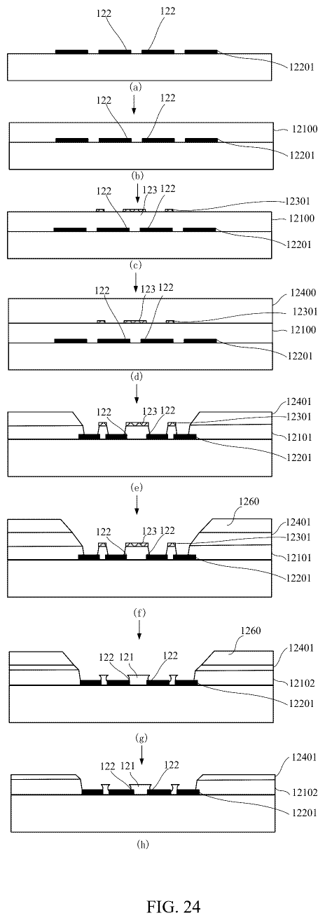

FIG. 24 is a schematic diagram of a flow of processing another isolation pillar according to some embodiments of the present disclosure, which can be applied to process the isolation pillar as shown in FIG. 8. Compared to the flow of processing shown in FIG. 23, the flow of processing differs as follows.

In a seventh step, as shown in part (g) of FIG. 24, the photoresist structure 1260 is used as a mask, and the second film layer 12102 is acquired and the third patterned film layer 12301 is removed by etching the second film layer 12102 and the third patterned film layer 12301 by, for example, a dry-etching method. The second film layer 12102 includes a plurality of I-shaped structures. Each of the first patterned film layer 12201 below the I-shaped structure has two ring structures. Optionally, in the process of etching the second patterned film layer 12101, the third patterned film layer 12301 made of the semiconductor material is equivalent to a template, and the first patterned film layer 12201 made of the metal material is equivalent to a substrate. As the etching rate of the inorganic insulating material is greater than the etching rate of the metal and semiconductor materials, that is, the etching rate of the etched layer is greater than the etching rate of the template and the substrate, an I-shaped structure is formed in the second patterned film layer 12101 upon etching.

In an eighth step, as shown in part (h) of FIG. 24, the photoresist structure 1260 is removed by a stripping process to acquire the isolation pillar as shown in FIG. 8.

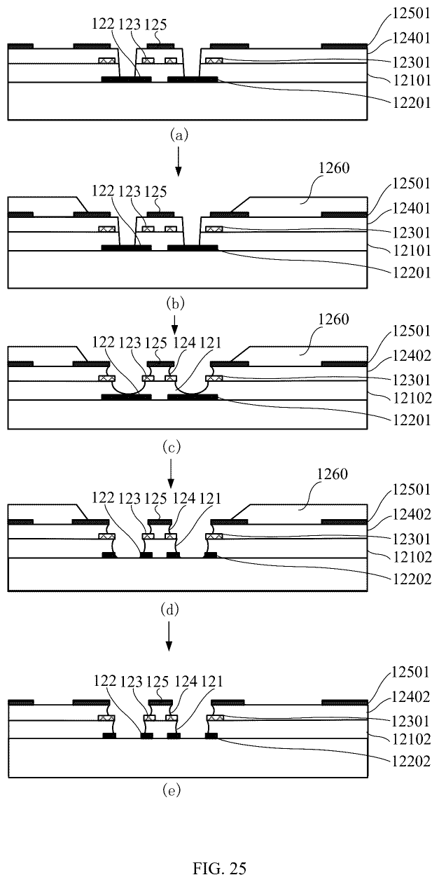

FIG. 25 is a schematic diagram of a flow of processing another isolation pillar according to some embodiments of the present disclosure, which is applied to process the isolation pillar as shown in FIG. 16 or FIG. 17. The flow of processing includes the following steps.

In a first step, as shown in part (a) of FIG. 25, a first patterned film layer 12201, a second patterned film layer 12102, a third patterned film layer 12303, a fourth patterned film layer 12401, and a fifth patterned film layer 12501 are formed by processes such as deposition and patterning. The fifth patterned film layer 12501 includes the third isolation ring 125, and the first patterned film layer 12201 includes the first isolation ring 122. The third patterned film layer 12301 includes the second isolation ring 123, and the second isolation ring 123 has two subrings. Optionally, the second patterned film layer 12102 is made of an inorganic insulating material, the fourth patterned film layer 12401 is made of an organic insulating material, and the third patterned film layer 12401 is made of a semiconductor material. Optionally, the fifth patterned film layer 12501 is made of an inert metal material such as silver, and the first patterned film layer 12201 is made of a metal material (e.g., molybdenum) that is less inert than silver.

In a second step, as shown in part (b) of FIG. 25, the photoresist structure 1260 is acquired by a process of photoresist coating, exposure, and development on a side, away from the second patterned film layer 12101, of the fifth patterned film layer 12501.

In a third step, as shown in part (c) of FIG. 25, the photoresist structure 1260 is used as a mask, and the second film layer 12102 and the fourth film layer 12402 are acquired by etching the second patterned film layer 12102 and the fourth patterned film layer 12401 by, for example, a dry etching method. The second film layer 12102 includes a first pillar 121, and the fourth film layer 12402 includes a second pillar 124.

In a fourth step, as shown in part (d) of FIG. 25, the first patterned film layer 12201 is etched to acquire the first film layer 12202, and the first film layer 12202 includes the first isolation ring 122. Optionally, in this step, the etching solution is an acidic etching solution. Only the first patterned film layer 12201 can be etched, and the fifth patterned film layer 12201 cannot be etched. The first film layer 12201 further includes an anode layer.

In a fifth step, as shown in part (e) of FIG. 25, the photoresist structure 1260 is removed by a stripping process to acquire the isolation pillar as shown in FIG. 16 or FIG. 17.

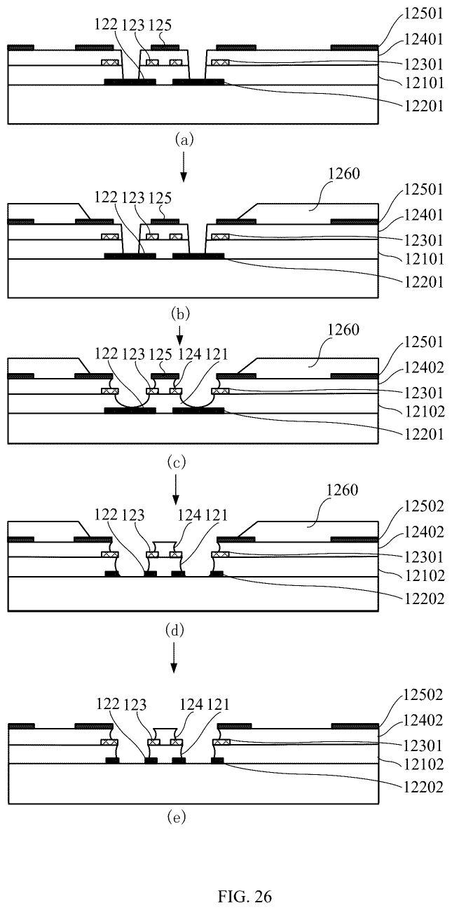

FIG. 26 is a schematic diagram of a flow of processing an isolation pillar according to some embodiments of the present disclosure, which can be applied to process the isolation pillar as shown in FIG. 15. Compared to the flow of processing shown in FIG. 25, the flow of processing differs as follows.

In a fourth step, as shown in part (d) of FIG. 26, a first patterned film layer 12201 is etched to acquire a first film layer 12202, and the first film layer includes a first isolation ring 122. The fifth patterned film layer 12501 is etched to remove a portion of the third patterned film layer 12501 on the second pillar 124 to acquire a fifth film layer 12502.

In a fifth step, as shown in part (e) of FIG. 26, the photoresist structure 1260 is removed by a stripping process to acquire the isolation pillar as shown in FIG. 15.

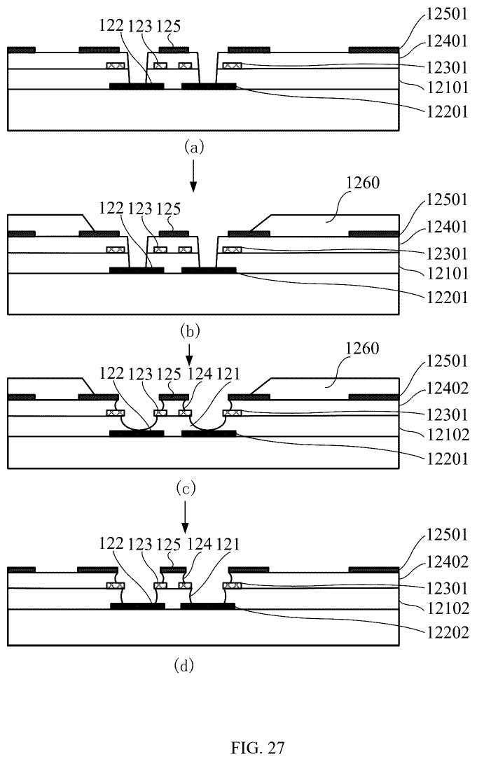

FIG. 27 is a schematic diagram of a flow of processing another isolation pillar according to some embodiments of the present disclosure, which can be applied to process the isolation pillar as shown in FIG. 10. Compared to the flow of processing shown in FIG. 25, the flow of processing differs as follows.

In a third step, as shown in part (c) of FIG. 27, the photoresist structure 1260 is used as a mask, and the second film layer 12102 and the fourth film layer 12402 are acquired by etching the second patterned film layer 12102 and the fourth patterned film layer 12401 by, for example, a dry-etching method. The second film layer 12102 includes a first pillar 121, and the fourth film layer 12402 includes a second pillar 124. In addition, the first patterned film layer 12201 includes a first isolation ring 122.

In a fourth step, as shown in part (d) of FIG. 27, the photoresist structure 1260 is removed by a stripping process to acquire the isolation pillar as shown in FIG. 10.

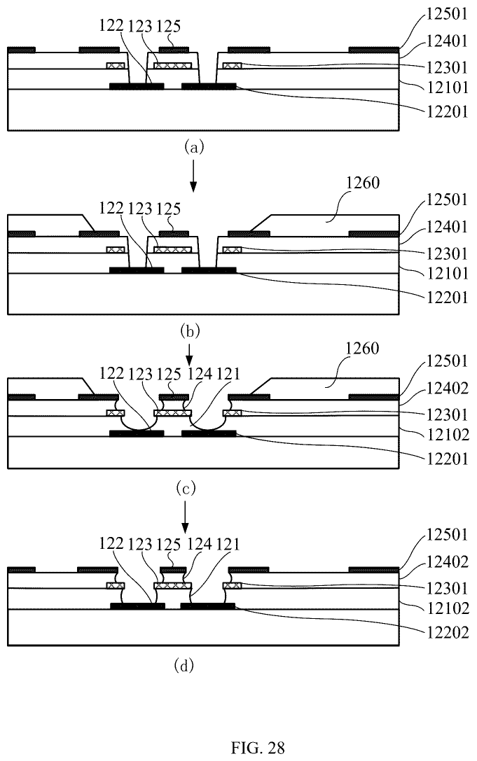

FIG. 28 is a schematic diagram of a flow of processing another isolation pillar according to some embodiments of the present disclosure, which can be applied to process the isolation pillar as shown in FIG. 13. Compared to the flow of processing shown in FIG. 25, the flow of processing differs as follows.

In a first step, as shown in part (a) of FIG. 28, the third patterned film layer 12301 includes a second isolation ring 123, and the second isolation ring 123 is an integrated structure.

In a second step, as shown in part (b) of FIG. 28, the photoresist structure 1260 is acquired by a process of photoresist coating, exposure, and development on a side, away from the second patterned film layer 12101, of the fifth patterned film layer 12501.

In a third step, as shown in part (c) of FIG. 28, the photoresist structure 1260 is used as a mask, and the second film layer 12102 and the fourth film layer 12402 are acquired by etching the second patterned film layer 12102 and the fourth patterned film layer 12401 by, for example, a dry etching method. The second film layer 12102 includes a first pillar 121, and the fourth film layer 12402 includes a second pillar 124.

In a fourth step, as shown in part (d) of FIG. 28, the photoresist structure 1260 is removed by a stripping process to acquire the isolation pillar as shown in FIG. 13.

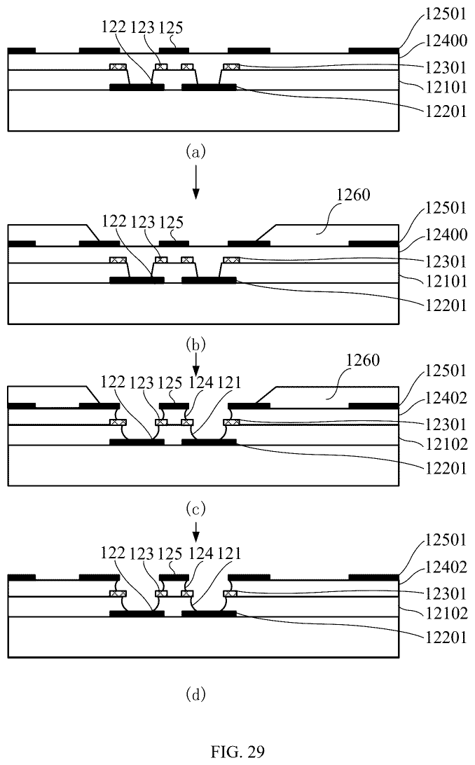

FIG. 29 is a schematic diagram of a flow of processing another isolation pillar according to some embodiments of the present disclosure, which can be applied to process the isolation pillar as shown in FIG. 10. The flow of processing includes the following steps.

In a first step, as shown in part (a) of FIG. 29, a first patterned film layer 12201, a second patterned film layer 12101, a third patterned film layer 12301, a fourth initialization film layer 12400, and a fifth patterned film layer 12501 are formed by a process such as deposition, and/or patterning. The first patterned film layer 12201 includes a first isolation ring 122, the first isolation ring 122 is two subrings, the third patterned film layer 12301 includes a second isolation ring 123, the second isolation ring 123 is two subrings, the fifth patterned film layer 12501 includes a third isolation ring 125, and the third isolation ring 125 is an integrated structure. Optionally, the second patterned film layer 12102 is made of an inorganic insulating material, the fourth membrane patterned film layer 12401 is made of an organic insulating material, and the third patterned film layer 12401 is made of a semiconductor material.

In a second step, as shown in part (b) of FIG. 29, the photoresist structure 1260 is acquired by a process of photoresist coating, exposure, and development on a side, away from the second patterned film layer 12101, of the fifth patterned film layer 12501.

In a third step, as shown in part (c) of FIG. 29, the photoresist structure 1260 is used as a mask, and the second film layer 12102 and the fourth film layer 12402 are acquired by etching the second patterned film layer 12102 and the fourth patterned film layer 12401 by, for example, a dry etching method. The second film layer 12102 includes a first pillar 121, and the fourth film layer 12402 includes a second pillar 124.

In a fourth step, as shown in part (d) of FIG. 29, the photoresist structure 1260 is removed by a stripping process to acquire the isolation pillar as shown in FIG. 10.

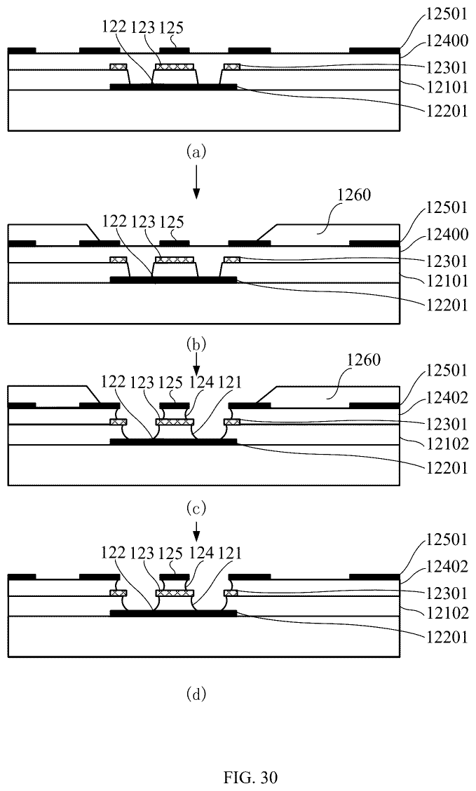

FIG. 30 is a schematic diagram of a flow of processing another isolation pillar according to some embodiments of the present disclosure, which can be applied to process the isolation pillar as shown in FIG. 10. Compared to the flow of processing shown in FIG. 29, the flow of processing differs as follows.

In a first step, as shown in part (a) of FIG. 30, the first patterned film layer 12201 includes a first isolation ring 122, and the first isolation ring 122 is an integrated structure. The third patterned film layer 12301 includes a second isolation ring 123, and the second isolation ring 123 is an integrated structure.

The other steps of processing are the same as the steps of processing shown in FIG. 29.

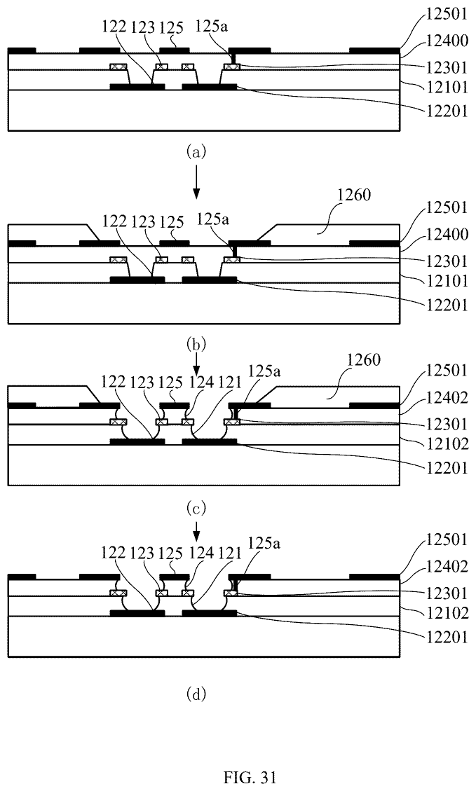

FIG. 31 is a schematic diagram of a flow of processing another isolation pillar according to some embodiments of the present disclosure, which can be applied to process the isolation pillar as shown in FIG. 13. Compared to the flow of processing shown in FIG. 29, the flow of processing differs as follows.

In a first step, as shown in part (a) of FIG. 31, a groove is processed in the fourth initialization film layer 12400, such that a portion of the fifth patterned film layer 12501 is disposed in the groove to form a block wall 125a. The first patterned film layer 12201 includes a first isolation ring 122, and the first isolation ring 122 is an integrated structure. The third patterned film layer 12301 includes a second isolation ring 123, and the second isolation ring 123 is an integrated structure.

The other steps of processing are the same as the steps of processing shown in FIG. 29.

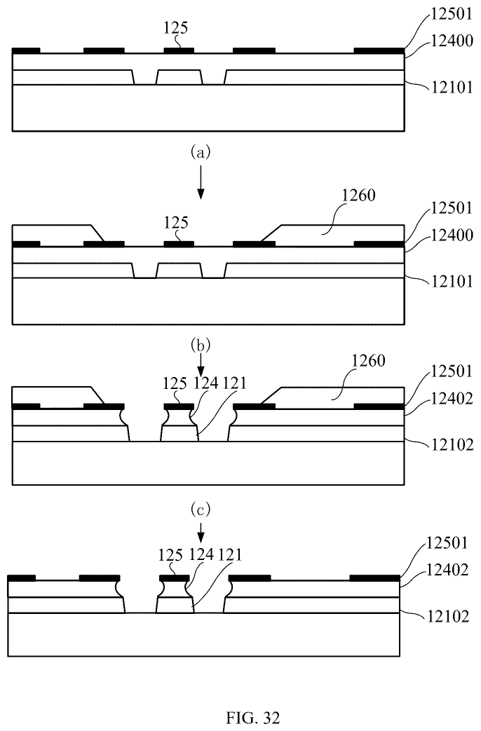

FIG. 32 is a schematic diagram of a flow of processing another isolation pillar according to some embodiments of the present disclosure, which can be applied to process the isolation pillar as shown in FIG. 14. Compared to the manufacturing process shown in FIG. 29, the manufacturing process is as follows.

In a first step, as shown in part (a) of FIG. 32, a second patterned film layer 12101, a fourth initialization film layer 12400, and a fifth patterned film layer 12501 are formed by a process such as deposition, and/or patterning. The first patterned film layer 12201 and the third patterned film layer 12301 are not formed, and no subsequent processing related to these two film layers is performed.

The other steps of processing are the same as the steps of processing shown in FIG. 29.

Optionally, the patterning includes processes such as photoresist coating, exposure, developing, etching, and stripping.

Optionally, as other backplane processes are not carried out upon etching the isolation pillar, problems such as bubbles and hole halos generated by coating film close to the opening region caused by the isolation pillar can be effectively avoided.

Embodiments of the present disclosure also provide a display device, the display device includes any of the above display panels and a power supply circuit, and the power supply circuit is configured to supply power to the display panel.

Exemplarily, the display device according to the embodiments of the present disclosure may be a cell phone, a tablet computer, a television, a monitor, a laptop computer, a digital photo frame, a navigator, and any other product or component having a display function.

The display device has the same effect as the above display panel, which is not repeated herein.

The above are only optional embodiments of the present disclosure and are not intended to limit the present application, and any modifications, equivalent substitutions, improvements and the like made within the spirit and principles of the present disclosure shall be included in the scope of protection of the resent disclosure.

1. A display panel, comprising:
a base substrate, comprising an opening region and a display region, wherein the display region surrounds the opening region; and
a plurality of isolation pillars, disposed on a first surface of the base substrate, wherein the plurality of isolation pillars are circular and surround the opening region;
wherein each of the plurality of isolation pillars comprises a first pillar made of an insulating material, wherein an isolation groove surrounding the opening region is disposed at both sides of the first pillar, and the first pillar has a first top surface away from the first surface, a first bottom surface close to the first surface, and a first sidewall and a second sidewall between the first top surface and the first bottom surface.

2. The display panel according to claim 1, wherein the first sidewall is close to the opening region and is recessed in a direction away from the opening region; and/or
the second sidewall is away from the opening region and is recessed in a direction close to the opening region.

3. The display panel according to claim 2, wherein each of the plurality of isolation pillars further comprises a first isolation ring, wherein the first isolation ring is disposed on a side, close to the first surface, of the first pillar, and the first isolation ring is made of a non-insulating material;
wherein the first isolation ring covers a bottom of the isolation groove; or
the first isolation ring comprises a first subring and a second subring which are sequentially disposed in a radially outward direction centered on a center of the opening region, wherein the first subring is disposed at an edge, close to the first sidewall, of the first bottom surface, and the second subring is disposed at an edge, close to the second sidewall, of the first bottom surface.

4. (canceled)

5. The display panel according to claim 1, wherein each of the plurality of isolation pillars further comprises a second isolation ring, wherein the second isolation ring is disposed on a side, away from the first surface, of the first pillar, and the second isolation ring is made of a non-insulating material;
wherein the second isolation ring covers the first top surface; or
the second isolation ring comprises a third subring and a fourth subring which are sequentially disposed in a radially outward direction centered on a center of the opening region, wherein the third subring is disposed at an edge, close to the first sidewall, of the first top surface, and the fourth subring is disposed at an edge, close to the second sidewall, of the first top surface.

6. (canceled)

7. The display panel according to claim 5, wherein each of the plurality of isolation pillars further comprises a second pillar, wherein the second pillar is disposed on a side, away from the first surface, of the first pillar and is made of an insulating material.

8. The display panel according to claim 7, wherein each of the plurality of isolation pillars further comprises a third isolation ring, wherein the third isolation ring is disposed on a side, away from the first surface, of the second pillar and is made of a non-insulating material.

9. The display panel according to claim 8, further comprising:
at least one block wall, wherein the at least one block wall is disposed in a layer in which the second pillar is disposed, and is connected to a layer in which the second isolation ring is disposed and a layer in which the third isolation ring is disposed;
wherein the at least one block wall comprises:
one first block wall, disposed on a side, close to the opening region, of a first isolation groove, wherein the first isolation groove is an isolation groove closest to the opening region of a plurality of isolation grooves; and/or
at least one second block wall, wherein each second block wall is disposed in one second pillar, and the second block wall is connected to the second isolation ring and the third isolation ring.

10. (canceled)

11. The display panel according to claim 1, wherein each of the plurality of isolation pillars further comprises a second pillar, wherein the second pillar is disposed on a side, away from the first surface, of the first pillar and is made of an insulating material.

12. The display panel according to claim 1, wherein in a radial direction of the opening region, a distance between an edge, close to the opening region, of an orthographic projection of the first top surface on the first surface and a contour line, away from the opening region, of an orthographic projection of the first sidewall on the first surface ranges from 0.1 to 2.0 μm; and/or
in the radial direction of the opening region, a distance between an edge, away from the opening region, of the orthographic projection of the first top surface on the first surface and a contour line, close to the opening region, of an orthographic projection of the first sidewall on the first surface ranges from 0.1 to 2.0 μm.

13. The display panel according to claim 1, wherein a dimension of the first top surface in a radial direction of the opening region ranges from 3 to 10 μm, and/or a distance between the first top surfaces of the first pillars of two adjacent isolation pillars ranges from 5 to 20 μm.

14. The display panel according to claim 7, wherein the second pillar has a second bottom surface close to the first surface, a second top surface away from the first surface, and a third sidewall and a fourth sidewall between the second top surface and the second bottom surface;
wherein the third sidewall is close to the opening region and recessed in a direction away from the opening region, and/or, the fourth sidewall is away from the opening region and recessed in a direction close to the opening region.

15. The display panel according to claim 14, wherein in a radial direction of the opening region, a distance between an edge, close to the opening region, of an orthographic projection of the second top surface on the first surface and a contour line, away from the opening region, of an orthographic projection of the third sidewall on the first surface ranges from 0.1 to 2.0 μm; and/or
in the radial direction of the opening region, a distance between an edge, away from the opening region, of an orthographic projection of the second top surface on the first surface and a contour line, close to the opening region, of an orthographic projection of the third sidewall on the first surface ranges from 0.1 to 2.0 μm.

16. The display panel according to claim 14, wherein a radial width of the second top surface is equal to a radial width of the first top surface, or the radial width of the second top surface is less than the radial width of the first top surface.

17. The display panel according to claim 7, wherein the first pillar is made of an inorganic insulating material, and the second pillar is made of an inorganic insulating material or an organic insulating material.

18. The display panel according to claim 1, further comprising a driving circuit layer and an anode layer which are sequentially stacked on the first surface, wherein the plurality of isolation pillars are disposed in a same layer as one or more layers in the driving circuit layer.

19. The display panel according to claim 1, further comprising a dam structure, wherein the dam structure is disposed on a surface, away from the first surface, of one of the plurality of isolation pillars, and the dam structure surrounds the opening region.

20. The display panel according to claim 19, further comprising a block ring, wherein the block ring is disposed on a surface, away from the first surface, of one of the plurality of the isolation pillars, and the block ring surrounds the dam structure; and
in a direction perpendicular to the first surface, a dimension of the block ring is less than a dimension of the dam structure.

21. The display panel according to claim 19, wherein the plurality of isolation pillars comprises a plurality of outer isolation pillars and a plurality of inner isolation pillars, wherein the plurality of outer isolation pillars are disposed on a side, close to the opening region, of the dam structure, and the plurality of inner isolation pillars are disposed on a side, away from the opening region, of the dam structure; and
a groove is disposed on a surface, away from the first surface, of at least one outer isolation pillar of the plurality of outer isolation pillars, and the display panel further comprises a filling structure disposed in the groove;
wherein at least a portion of the isolation pillar is made of an inorganic insulating material, at least a portion of the groove is disposed in the portion of the isolation pillar made of the inorganic insulating material, and the filling structure is made of an organic insulating material.

22. (canceled)

23. A method for manufacturing a display panel, comprising:
providing a base substrate, wherein the base substrate comprises an opening region and a display region, the display region surrounding the opening region; and
processing a plurality of isolation pillars on a first surface of the base substrate;
wherein the plurality of isolation pillars are circular and surround the opening region, each of the plurality of isolation pillars comprises a first pillar made of an insulating material, wherein an isolation groove surrounding the opening region is disposed at both sides of the first pillar, and the first pillar has a first top surface away from the first surface, a first bottom surface close to the first surface, and a first sidewall and a second sidewall between the first top surface and the first bottom surface.

24. A display device, comprising a power supply circuit and a display panel, wherein the power supply circuit supplies power to the display panel; and
the display panel comprises:
a base substrate, comprising an opening region and a display region, wherein the display region surrounds the opening region; and
a plurality of isolation pillars, disposed on a first surface of the base substrate, wherein the plurality of isolation pillars are circular and surround the opening region;
wherein each of the plurality of isolation pillars comprises a first pillar made of an insulating material, wherein an isolation groove surrounding the opening region is disposed at both sides of the first pillar, and the first pillar has a first top surface away from the first surface, a first bottom surface close to the first surface, and a first sidewall and a second sidewall between the first top surface and the first bottom surface.
